(19) United States
(12) Patent Application Publication
(10) Pub. No.: US 2026/0349862 A1
(43) Pub. Date: Nov. 5, 2026

(54) METHOD FOR BACKWARD FAILURE PROPAGATION IN CONCEPTUAL SYSTEM DESIGN

(71) Applicant: Ohio State Innovation Foundation, Columbus, OH (US)

(72) Inventors: Ali MANSOOR, Columbus, OH (US); Carol Sophie SMIDTS, Columbus, OH (US); Xiaoxu DIAO, Columbus, OH (US)

(21) Appl. No.: 19/122,542

(22) PCT Filed: Oct. 23, 2023
(86) PCT No.: PCT/US2023/077510

§ 371 Date: Apr. 18, 2025

Related U.S. Application Data
(60) Provisional application No. 63/380,632, filed on Oct. 24, 2022.

(51) Int. Cl. G06F 11/07

(52) U.S. Cl. CPC G06F 11/0766; G06F 11/0715

(57) ABSTRACT

A method for backward propagation of failures in a system includes extracting or deriving reverse functional failure logic (RFFL) for a function having a known state, identifying relevant components associated with the function, generating reverse behavior rules (RBRs) for the relevant components from first behavior rules (BRs), determining variable relations for the relevant components, identifying adjacent components connected to the relevant components, identifying RBRs for the adjacent components from second BRs; determining second variable relations for the adjacent components based on the second RBRs; determining valid modes for each of the relevant components and each of the adjacent components based on constraints of the system; and estimating (i) a state for one or more additional functions of the system related to the set of relevant components, and (ii) a state for one or more functions of the system related to the set of adjacent components.

### CROSS-REFERENCE TO RELATED APPLICATIONS

This application claims priority to and the benefit of U.S. Provisional Patent App. No. 63/380,632, filed Oct. 24, 2022, which is incorporated herein by reference in its entirety.

### BACKGROUND

The safe operation of systems with higher failure consequences is vital for the safety of the public and the environment. However, as modern systems have become more complicated and time to market has decreased, safety verification and validation have become more difficult. One approach to address this situation is integration of safety at the design stage. System failure analysis early in the design process effectively reduces risk, maintains constancy between safety and system design, and provides economic advantages due to fewer design changes, fewer project delays, and lower validation time.

### SUMMARY

One implementation of the present disclosure is a method for backward propagation of failures in a system, the method including: extracting, from a model of the system, reverse functional failure logic (RFFL) for at least one function of the system having a known state, wherein the RFFL is an inverse of predefined function failure logic (FFL) for the at least one function; identifying a set of relevant components of the system associated with the at least one function; generating first reverse behavior rules (RBRs) for each of the set of relevant components from predefined first behavior rules (BRs); determining first variable relations for each of the set of relevant components, wherein the first variable relations are qualitative equations depicting a relation between physical variables of respective components of the set of relevant components; identifying a set of adjacent components of the system, each of the set of adjacent components connected to at least one of the set of relevant components in the model of the system; identifying second RBRs for each of the set of adjacent components from predefined second BRs, determining second variable relations for each of the set of adjacent components based on the second RBRs, wherein the second variable relations are qualitative equations depicting a physical connection between each of the set of adjacent components and a corresponding one of the set of relevant components; determining valid modes for each of the set of relevant components and each of the set of adjacent components based on constraints of the system; and estimating, based on the valid modes, (i) a state for one or more additional functions of the system related to the set of relevant components, and (ii) a state for one or more functions of the system related to the set of adjacent components.

In some implementations, the method further includes determining valid modes for each of the set of relevant components prior to generating the first RBRs.

In some implementations, the method further includes identifying the one or more additional functions of the system related to the set of relevant components based on the valid modes for the set of relevant components.

In some implementations, the state for the one or more additional functions of the system related to the set of relevant components is estimated based on FFL of the set of relevant component in addition to the valid modes.

In some implementations, the state for the one or more functions of the system related to the set of adjacent components is estimated based on FFL of the set of adjacent component in addition to the valid modes.

In some implementations, the method further includes removing, from the set of adjacent components, any adjacent component that is also found in the set of relevant components.

In some implementations, the method further includes evaluating at least one of the first variable relations or the second variable relations against constraints defined in the model of the system.

In some implementations, the valid modes for each of the set of relevant components and each of the set of adjacent components based on constraints of the system are further determined based on the evaluation with respect to the constraints.

In some implementations, the constraints are expressions relating to physical variables that describe limitations of the system.

Another implementation of the present disclosure is a system including: at least one processor; and memory having instructions stored thereon that, when executed by the processor, cause the system to: extract, from a model of an external system, reverse functional failure logic (RFFL) for at least one function of the external system having a known state, wherein the RFFL is an inverse of predefined function failure logic (FFL) for the at least one function; identify a set of relevant components of the external system associated with the at least one function; generate first reverse behavior rules (RBRs) for each of the set of relevant components from predefined first behavior rules (BRs); determine first variable relations for each of the set of relevant components, wherein the first variable relations are qualitative equations depicting relationships between physical variables of respective components of the set of relevant components; identify a set of adjacent components of the external system, each of the set of adjacent components connected to at least one of the set of relevant components in the model of the external system; identify second RBRs for each of the set of adjacent components from predefined second BRs; determine second variable relations for each of the set of adjacent components based on the second RBRs, wherein the second variable relations are qualitative equations depicting a physical connection between each of the set of adjacent components and a corresponding one of the set of relevant components; determine valid modes for each of the set of relevant components and each of the set of adjacent components based on the first variable relations and the second variable relations, respectively; and estimate, based on the valid modes, (i) a state for one or more additional functions of the external system related to the set of relevant components, and (ii) a state for one or more functions of the external system related to the set of adjacent components.

In some implementations, the instructions further cause the system to: determine valid modes for each of the set of relevant components prior to generating the first RBRs.

In some implementations, the instructions further cause the system to: identify the one or more additional functions of the external system related to the set of relevant components based on the valid modes for the set of relevant components.

In some implementations, the state for the one or more additional functions of the external system related to the set of relevant components is estimated based on FFL of the set of relevant component in addition to the valid modes.

In some implementations, the state for the one or more functions of the external system related to the set of adjacent components is estimated based on FFL of the set of adjacent component in addition to the valid modes.

In some implementations, the instructions further cause the system to: remove, from the set of adjacent components, any adjacent component that is also found in the set of relevant components.

In some implementations, the instructions further cause the system to: evaluate at least one of the first variable relations or the second variable relations against constraints defined in the model of the external system to determine the valid modes.

In some implementations, the valid modes for each of the set of relevant components and each of the set of adjacent components are further determined based on the evaluation with respect to the constraints.

In some implementations, the constraints are expressions relating to physical variables that describe limitations of the external system.

Yet another implementation of the present disclosure is a non-transitory computer readable medium having instructions stored thereon that, when executed by the processor, cause a device to: extract, from a model of a system, reverse functional failure logic (RFFL) for at least one function of the system having a known state, wherein the RFFL is an inverse of predefined function failure logic (FFL) for the at least one function; identify a set of relevant components of the system associated with the at least one function; generate first reverse behavior rules (RBRs) for each of the set of relevant components from predefined first behavior rules (BRs); determine first variable relations for each of the set of relevant components, wherein the first variable relations are qualitative equations depicting a relation between physical variables of respective components of the set of relevant components; identify a set of adjacent components of the system, each of the set of adjacent components connected to at least one of the set of relevant components in the model of the system; identify second RBRs for each of the set of adjacent components from predefined second BRs; determine second variable relations for each of the set of adjacent components based on the second RBRs, wherein the second variable relations are qualitative equations depicting a physical connection between each of the set of adjacent components and a corresponding one of the set of relevant components; determine valid modes for each of the set of relevant components and each of the set of adjacent components based on constraints of the system; and estimate, based on the valid modes, (i) a state for one or more additional functions of the system related to the set of relevant components, and (ii) a state for one or more functions of the external related to the set of adjacent components.

In some implementations, the instructions further cause the device to: remove, from the set of adjacent components, any adjacent component that is also found in the set of relevant components.

Additional advantages will be set forth in part in the description which follows or may be learned by practice. The advantages will be realized and attained by means of the elements and combinations particularly pointed out in the appended claims. It is to be understood that both the foregoing general description and the following detailed description are exemplary and explanatory only and are not restrictive, as claimed.

### BRIEF DESCRIPTION OF THE DRAWINGS

FIG. 1 is a diagram illustrating a backwards failure propagation methodology, according to some implementations.

FIG. 2 is a flow diagram of backwards failure propagation, according to some implementations.

FIG. 3 is a diagram of an example system for demonstrating inference, according to some implementations.

FIG. 4 is a diagram of the state of an example system relating to a specific state of a function, according to some implementations.

FIGS. 5A-SD are diagrams of the backwards logic inference based propagation for system analysis (BLIPS) technique described herein, according to some implementations.

FIGS. 6A and 6B are diagrams of example branches obtained using BLIPS, according to some implementations.

FIGS. 7A-7D are diagrams of example observed-parameters of a branch at the component level, according to some implementations.

FIG. 8 is a diagram of a system for implementing BLIPS, according to some implementations.

FIG. 9 is a flow chart of a process for backwards failure propagation, according to some implementations.

FIGS. 10A and 10B are flow charts of an implementation of BLIPS, according to some implementations.

Various objects, aspects, features, and advantages of the disclosure will become more apparent and better understood by referring to the detailed description taken in conjunction with the accompanying drawings, in which like reference characters identify corresponding elements throughout. In the drawings, like reference numbers generally indicate identical, functionally similar, and/or structurally similar elements.

### DETAILED DESCRIPTION

Described herein are a system and methods for deductive failure analysis, according to various implementations. Specifically, in at least one aspect, a deductive failure analysis method referred to herein as “Backwards Logic Inference-Based Propagation for System analysis” or “BLIPS” is described. Backward failure propagation is initiated with a given state of the system, which includes either a known states of one or more functions, mode(s) of component(s), a physical variable(s) of components, or a combination of these elements. A functional state is used to infer component modes and the relations of physical variables (e.g., qualitative equations showing the relationship between physical variables of the components). Then, the state(s) of other functions are assessed to deduce inter-functional dependence. The qualitative equations depicting the relation between the physical variables of the components are referred to as “variable relations.” The known functional state(s) are used to infer the mode(s) of the component(s) and variable relations for the components that serve that function; these component(s) are called “relevant components” hereafter. The component(s) which are connected to the relevant component(s) (e.g., the immediate neighboring components to the relevant component(s)) are called “adjacent component(s)” hereafter. The variable relations of the relevant component(s) are used to infer the variable relations of the adjacent component(s). The modes of the adjacent component(s) and the state(s) of the functions related to the adjacent component(s) are then inferred based on the variable relations of the adjacent component(s).

In some implementations, BLIPS can be enhanced using Probabilistic Augmentation (PA) to improve the interpretation of results by assessing the effect of variation in likelihood of states of controlled parameters on the system being analyzed. Additional discussion and features of BLIPS, including a system for implementing BLIPS, are discussed in greater detail below. Additionally, an index of terms utilized throughout this disclosure is provided below in Table VI.

### Overview

Various methodologies have been developed to diagnose the defects in operational electro-mechanical and digital systems, including mathematical system-model approaches, data-driven methods, and signal-based methods. These strategies require a fully functional system design, prototype, or implementation for these strategies to work. Data-driven approaches, such as artificial neural networks (ANNs), necessitate a knowledge base and system training before fault identification and diagnosis, which are not available during the early design stage. Finalized designs are also necessary for model-based and signal-based techniques. A function-based technique can be used to overcome the constraints of such methods. Fault analysis during the design stage, on the other hand, aids the designer in developing a robust early design and reduces the need for design modifications.

Integrated System Failure Analysis (ISFA) is one of the function-based approaches that traverses the faults through a system to identify their consequences. However, in a conceptual design phase, a designer would be naturally interested in identifying the faults that may lead to a system failure of interest. For instance, a safety analyst would be interested in identifying the conditions that may lead to a loss of coolant accident in a pressurized water reactor (PWR). Therefore, an instinctive analysis approach would be to identify the system faults that may lead to the accident of interest. Such an analysis provides a deductive assessment, e.g., a backward propagation of failure, to identify the possible system states that may lead to a specific or a combination of consequences. For an initial condition, when one or more functional states are known, the suggested method for backward failure propagation aims to identify the component modes, state(s) of other functions, and relationships between physical variables.

Using the methods described herein to perform safety analysis at an early design stage would allow for more robust early design against severe failures as the number of major design changes would be significantly reduced. Moreover, it will enable the identification of possible component modes and the combination of physical variables that co-exist with the functional state of interest, which would be a more involved activity if it is performed using an inductive approach. The disclosed methods are applicable in various engineering industries, e.g., nuclear, electrical, chemical, aerospace, etc.

As mentioned above, the disclosed methods can be used to formally perform deductive analysis of systems. In this regard, the results are mathematically proved by evaluating the truth values of all the combinations of parameters present in the parameter-space, which includes states of the functions, modes of the components, combinations of physical variables in a component and across the backward-tracked sequences. Other physics-based methods validate the physics for given scenarios; however, the disclosed methods prove valid and invalid conditions over the entire variable space. The entire variable space is evaluated for truthfulness, which means that all the combinations of variables, for an individual component and across a series of components, are logically proved or disproved based on the logic expression(s) defined using the system's physics. Moreover, symbolic inference can prove/disprove numerous system states in one pass, while innumerable simulations may be required to obtain the same conclusion using physics-based methods that use numerical methods.

The methods described herein can use propositional logic (PL) to translate the physics of a system from conditional-statements to logic-expressions suitable for mathematical operations. PL, which is also known as sentential logic, allows the representation of general sentences as formal logical expressions. These logical expressions can be evaluated for the satisfiability of a system's model, which can be performed using a Satisfiability Modulo Theories (SMT) based solver. It may be noted that adopting a SMT solver for this method allows us to define the system using a higher-order logic. SMT-based verification has been widely used in the software industry for the verification of programs, though, it has not been used for deductive failure propagation analysis. The unavailability of operational and failure data for novel engineering designs makes the physics-based verification of an abstract design a fruitful option. Therefore, building on PL, SMT-based verification for novel system designs is discussed below.

Although inductive fault analysis (forward-looking) has its own significance, a designer would innately prefer to trace failures backward and remedy the causes of those failures, as compared to a more cumbersome activity of identifying the faults individually and sifting through the combinations that lead to the failure of interest. Thus, the disclosed backward failure propagation methodology (e.g., BLIPS) can be used to analyze the origins of functional failures in a conceptual design of systems. BLIPS allows the designer to achieve a robust early design by identifying the causes that lead to critical system failures before proceeding to the detailed design and testing stages. The insights provided by the analysis at the conceptual design stage also reduce re-design efforts, testing costs, and project completion time.

As mentioned above, BLIPS is a backward failure propagation method which leverages the reverse of the rules used in ISFA. In this regard, the BLIPS methodology includes translation of ISFA rules into the propositional logic's syntax; inversion of the Functional Failure Logic (FFL) and component Behavioral Rules (BRs) using rules of inference; and propagation of the assumed initial condition to assess valid states of a system that are logically satisfiable. The entire state space for the parameters of the system is proved or disproved for the given premises. The satisfiability of the system's states can be checked with an SMT solver.

As expected, deductive analysis generates the backward propagation sequences which are mutually exclusive and form an exhaustive set. The number of sequences (or branches) is very likely to be intractable for a complex system; hence, a relative weight can be assigned to each sequence so that a designer could treat each failure sequence based on their relative importance. Such a representation in terms of the relative probability of a sequence would provide the user with a deeper insight into the results which will enable more informed decisions; the method overlaying the probabilistic view is referred to as PA, as mentioned above.

Deductive reasoning is a truth-preserving approach; therefore, any conclusion drawn using this approach is an assertion. These conclusions are drawn based on premises (e.g., an assumed state of the system, rules capturing the physics of the system, and system constraints) and principles of logic. In order to view such conclusions (e.g., failure sequences) in terms of likelihood-of-occurrence in comparison to other conclusions, certain prior information is needed—referred to herein as the observable parameters (e.g., the parameters whose states are known)—and the probabilities for the controlled parameters. Such information can be obtained from operational history, testing data, experts' opinions, or assuming the probability of occurrence of the modes follows a uniform prior. Furthermore, as BLIPS deals with systems which are defined in terms of logic statements with different levels of abstraction, there exists an imprecision in the rules that relate to the levels of abstraction when the rules are reversed. This imprecision is addressed using fuzzy logic, as discussed below.

As mentioned above, PA is a two-pronged approach. The first part of this approach deals with the assessment of the conditional probability of a component mode given functional state(s). For failure analysis, the assumed functional states usually correspond to the failed states of a system. To address the imprecision between the functional level and the component level, the rules defining the relationship between these levels of abstraction are fuzzified. As described below, the conditional probability of a mode of a component given a state(s) of a function(s) is estimated using fuzzified Reversed Functional Failure Logic (RFFL), membership functions related to the fuzzy RFFLs, and the prior probability of the controlled parameters as inputs to perform the calculus. The second part of PA deals with the assessment of probability at the component level. The joint probability for the parameters in a sequence at the component level is a conditional probability that is calculated given the state(s) of the observable parameter(s) in the sequence. The calculus of this probability utilizes the prior probabilities of the controlled parameters and identification of the observed parameters (e.g., which serve as the condition).

PA is a valuable extension to BLIPS that quantifies the importance of each failure sequence relative to all other sequences identified for that failure. PA provides sensitivity plots showcasing the effect of controlled parameters on a failure-sequence. The likelihood of controlled parameters can be obtained for operational history, expert opinion, design specifications, regulatory requirements, etc. This likelihood can be a single numerical value or a range of values. Using a range of values is particularly useful when uncertainties exist regarding the prior probabilities, in such cases, the parameters' probabilities can be defined within a numerical range, allowing for the observation of the system's behavior across that range. One way to observe the probability intervals of controlled parameters versus the probability of a sequence is by graphical representation (plots); however, it may become humanly impossible to visually observe the graphical plots when dealing with a large number of parameters simultaneously. To handle multiple parameters simultaneously, especially when dealing with more than two parameters, machine learning algorithms may be used to analyze probabilistic outcomes. These algorithms provide a valuable tool for efficiently processing and interpreting complex data sets involving numerous variables.

ISFA has been applied for various inductive analyses including sensor deployment, failure diagnosis, online monitoring system, ontology-based analysis for safety-critical computer systems, risk analysis of functional failure, etc. For an inductive analysis, a single fault or a combination of faults is introduced in a system at the component level, which is then inductively propagated through the system while assuming a normal initial state of the system. Upon the completion of the analysis, modes of components, state of functions, and the combination of physical variables are available at each time step. The “introduction of a fault” refers to introducing deviations in component variable(s) values.

### Backwards Logic Inference Based Propagation for System Analysis (BLIPS)

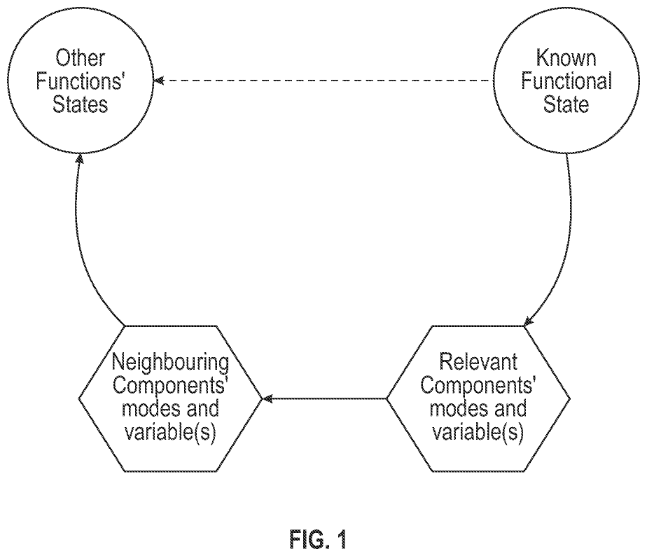

Referring first to FIG. 1, a high-level diagram of the disclosed backward failure propagation method is shown, according to some implementations. As mentioned above, backward failure propagation is initiated with known states of one or more functions to estimate component modes, and the relations of physical variables (e.g., qualitative equations showing the relationship between physical variables of the components). The analysis can be further extended to assess the state(s) of other functions to deduce inter-functional dependence. The qualitative equations depicting the relation between the physical variables of the components are referred to as ‘variable relations’ from here onwards. The known functional state(s) are used to infer the mode(s) of the component(s) and variable relations for the components that serve that function; these component(s) are called ‘relevant components’ hereafter. The component(s) which are connected to the relevant component(s), i.e., the immediate neighboring components to the relevant component(s), are called ‘adjacent component(s)’ hereafter. The variable relations of the relevant component(s) are used to infer the variable relations of the adjacent component(s). The modes of the adjacent component(s) and the state(s) of the functions related to the adjacent component(s) are then inferred based on the variable relations of the adjacent component(s).

Moreover, the component modes and the variable relations are recorded along the propagation path. This enables an analyst to observe all the possible combinations of component modes that may lead to functional failure(s) of interest and the states of the other functions. Each component along the path at which the inference is performed is called a ‘node’. It is noted that this specific configuration of the backward failure propagation method deals with the analysis for a single time-step in the past; in other words, the backward propagation across one node/component considers the variable relations that may hold true in one time-step in the past. Nevertheless, there may be other possible combinations at the same preceding node if traced back further in the time domain.

Reversal of the ISFA Rules: Forward application of the ISFA method utilizes logic-based rules known as BR and FFL, as mentioned above. However, for application to backward propagation, a reversed version of the rules are derived. The derivation of the reverse rules is performed using PL, which is a mathematical technique used, e.g., in computer science to verify software and design computing and AI systems. PL is a branch of mathematical logic that combines simple propositions to make more complicated propositions and studies the logical relationships and properties derived from manipulating the statements. The propositions are the simplest statements that cannot be further sub-divided. A proposition can be either ‘true’ or ‘false’ but cannot have both truth values simultaneously. The value of a complex statement depends upon the truth values of the comprising propositions. The simple propositions are combined using connectives to make complex statements. These complex statements can be studied based on the axioms of propositional logic and the rules of inference of propositional logic. A set of statements, called premise, can be used to derive a new statement or a new set of statements. For the sake of simplicity and improved readability, a logic connective called multi-XOR, \tilde{⊕}, is introduced herein, which is defined as (Equation 1):

a₁\tilde{⊕}a₂\tilde{⊕} . . . \tilde{⊕}aₙ≡{a₁∧¬(a₁∨ . . . ∨aₙ)}∨{¬a₁∧a₂∧¬(a₃∨ . . . ∨aₙ)}∨{¬(a₁∨a₂)∧a₃∧¬(a₄∨ . . . ∨aₙ)}∨ . . . ∨{¬(a₁∨ . . . ∨aₙ−1)∧¬aₙ}

In traditional ISFA BRs, the mode of a component is implied given a certain combination of physical variables. Table I shows ISFA BRs in terms of if/then conditional statements for an example “tank” component. These statements are converted to mathematical expressions, e.g., using PL, to make them suitable for mathematical operations. Conditional statements are defined as implications in the PL semantics. To formalize the ISFA rules, assume that each component of a given system, ‘C’, belongs to the set, ‘C’, that contains all the components of the system and that each mode of a component, M′, belongs to the set, ‘M’, that contains all the modes of the component. These modes are mutually exclusive and exhaustive. Then a component may have multiple BRs, ‘s’, and each behavioral rule—which is a function of the input and the output variables of a component—is mathematically defined to represent the mapping of a component's inputs and output physical variables onto the mode of component, as (Equation 2):

BRj [symbol] (OpV?IpV)₁¿ . . . ¿(OpV?IpV)ᵥ→(Mode(Cᵤ)=M_{w}),Cu∈C,Mw∈M

where ‘w’, ‘u’ and ‘j’ is the indexes for modes of a component in ‘M’, components in ‘C’ and BRs for a component, respectively, ‘?’ refers to mathematical operators, i.e., ‘=’, ‘<’, ‘>’, etc.; ‘¿’ refers to logical operators, i.e., ‘∧’, ‘∨’, ‘⊕’, etc.; and ‘v’ is the index for types of variables—e.g. flowrate, pressure, current, etc.—for ‘Cᵤ’.

TABLE I
Tank's FFL and BRs for traditional ISFA

```
    FFL
  (O - operating, L - Lost)
```

| | |
|---|---|
| [symbol] | IF mode = Nominal Then Supply fluid=O ∧ Store fluid=O |
| [symbol] | IF mode = Overflow Then Store fluid = L |
| [symbol] | IF mode = Dryout Then Supply fluid = L |

```
    BRs
(L - Level, LTH - Lower threshold, UTH - Upper threshold,
    Qₒᵤₜ - Flowrate out, Qᵢₙ - Flowrate in)
```

| | |
|---|---|
| [symbol] | Mode = Nominal IF {( L>L_{LTH})∧( L<L_{UTH} )}∧{ Qₒᵤₜ=Qᵢₙ} |
| [symbol] | Mode = Dryout IF { L ≤ L_{LTH} } |
| [symbol] | Mode = Overflow IF { L ≥ L_{UTH} } |

Similarly, the conditional statements for functional failure logic are defined using PL semantics. Assume that each function of a given system, ‘F’, belongs to the set, ‘F’, that contains all the functions of a system; and that each state a function, ‘S’, belongs to the set, ‘S’, that contains all the states of a function (e.g., operating, lost, degraded) which are mutually exclusive and exhaustive. Further, the CR is the set of components that implement a given function, and C_{R}⊆C. Then a function may have multiple FFLs, where one FFL—which is a function of component mode—is mathematically defined to represent the mapping of a component's mode onto the state of a function (Equation 3):

FFLk [symbol] (Mode(C_{u′})=M_{w})→(State(Fₕ)=Sₚ),Cu′∈CR,Mw∈M,Fh∈F,Sp∈S

where ‘p’, ‘u’, ‘h’, and ‘k’ are the indexes for states of a function in set ‘S’, components in ‘C_{R}’, functions in ‘F’, and FFL of a function, respectively.

The application of these rules for the inductive analysis (e.g., the traditional application of ISFA) begins with a fault injection at the component level by specifying expressions(s) for the relationship between input and output physical variables (e.g., for pressure and voltage, (Pₒᵤₜ<Pᵢₙ), (Vₒᵤₜ=Vᵢₙ), etc.). The BRs, which are the functions of specified input and output physical variables, BRⱼ(OpV,IpV), along with the constraints for those physical variables, are used to infer the mode of a component. The constraints refer to logical expressions constraining the co-existence of exclusive relationships between the input and output physical variables—for instance, high, equal, and low pressure are mutually exclusive (e.g., [(Pₒᵤₜ<Pᵢₙ)\tilde{⊕}(Pₒᵤₜ>Pᵢₙ)\tilde{⊕}(Pₒᵤₜ=Pᵢₙ)])—and invalid relationships, e.g., flow rate less than zero. Each BR of a component (which is a function of specified physical variables), when combined with a specific combination of physical variables and the system constraints, will infer a mode of the component. This can be mathematically represented as (Equation 4):

{BRⱼ(OpV,IpV)∧[(OpV?IpV)₁¿ . . . ¿(OpV?IpV)ᵥ]∧Constraints} [symbol] (Mode(Cᵤ)=M_{w})

As a component's behavior is defined using multiple BRs, upon assessing all the pertinent BRs for a component, mode(s) M₁\tilde{⊕}M₂\tilde{⊕} . . . \tilde{⊕}M_{w} for the component ‘Cᵤ’ are obtained. It may be noted that the modes are mutually exclusive to each other, therefore, each mode would refer to a branch for the inductive propagation. For a total of ‘s’ BRs of ‘Cᵤ’, the extraction of modes is expressed as (Equation 5):

$$( {∧}_{j = 1}^{s} {BR}_{j} ( OpV , IpV ) ∧ [ {( OpV ? IpV )}_{1} ¿ … {¿ ( OpV ? IpV )}_{v} ] ∧ Constraints ) ⊨ ( ( Mode ( {C}_{u} ) = {M}_{1} ) \tilde{⊕} ( Mode ( {C}_{u} ) = {M}_{2} ) \tilde{⊕} … \tilde{⊕} ( Mode ( {C}_{u} ) = {M}_{w} ) )$$

Then for each mode of the component, the state(s) of function(s) are inferred using the FFLs. An FFL is a function of the component-modes obtained from BRs, FFLₖ(M_{w}). As each function has multiple FFLs, the modes obtained from Eq. 5 in combination with an FFL will yield a state of a function (Equation 6):

{FFLₖ(M_{w})∧(Mode(Cᵤ)=M_{w})} [symbol] (State(Fₕ)=Sₚ)

Upon assessing all the pertinent FFLs of a function, S₁\tilde{⊕}S₂\tilde{⊕}Sₚ for ‘Fₕ’ are obtained (Equation 7):

$$[ {∧}_{k = 1}^{t} {FFL}_{k} ( Mode ( {C}_{u} ) = {M}_{1} , Mode ( {C}_{u} ) = {M}_{2} , … , Mode ( {C}_{u} ) = {M}_{w} ) ] ∧ Mode ( {C}_{u} ) = {M}_{w} ⊨ ( ( State ( {F}_{h} ) = {S}_{1} ) \tilde{⊕} ( State ( {F}_{h} ) = {S}_{2} ) \tilde{⊕} … \tilde{⊕} ( State ( {F}_{h} ) = {S}_{p} ) )$$

The reversed rules derived from the forward FF) and the forward BRs are referred to as the Reverse Functional Failure Logic (RFFL) and the Reverse Behavior Rules (RBRs), respectively. The reverse implication is primarily governed by the contrapositive rule and simplification using the rules of propositional logic (Equation 8):

(a→b)↔(¬b→¬a)

After an FFL is re-written using the rule form Equation 8, the RFFL can be derived using the rules of inference and the equivalence laws of the propositional logic. A function associates with two or more RFFLs, depending upon the number of states the function is mapped onto. Each RFFL represents modes of components implied by a state of a function (Equation 9):

RFFLₖ_{^{r}} [symbol] (State(Fₕ)=Sₚ)→((Mode(C_{u′})=M₁)¿ . . . ¿(Mode(C_{u′})=M_{w})),Cu′CR,Mw∈M,Fh∈F,Sp∈S

where ‘k′’ is the index for RFFLs of a function.

For the derivation of RBRs, BRs and constraints on the component variable are used as the premises. The derivation is carried out using the same procedure as FFL, e.g., by contraposition and simplification. A component may have multiple RBRs, each of them presenting a combination of the physical variables of a component as implied by the mode of that component (Equation 10):

RBRⱼ_{^{r}} [symbol] ((Mode(Cᵤ)=M₁)¿ . . . ¿(Mode(Cᵤ)=M_{w}))→(OpV?IpV)₁¿ . . . ¿(OpV?IpV)ᵥ,Cᵤ∈C,M_{w}∈M

where ‘j′’ is the index for RBRs of a component.

The FFL and BRs in the traditional ISFA for a component (e.g., a tank) are shown in Table I, above. For example, the state of functions ‘Supply fluid’ and ‘Store fluid’ is operating when the component ‘Tank’ is in ‘nominal’ mode; and mode of Tank is nominal when the level of fluid is between upper and lower threshold levels while the input flowrate is equal to the output. Tank is the most used component in process engineering for storing fluids. The details about the variables associated with the component ‘Tank’ are given in Table II.

TABLE II
Description of physical variables for Tank and Pipes

| | Component | | | | | | |
|---|---|---|---|---|---|---|---|
| | Pipe | | Tank | | | | |
| Variable | Q_{iP} | Q_{oP} | Q_{iT} | Q_{oT} | L_{UTH} | L_{LTH} | L |
| Meaning | Input | Output | Input | Output | Upper | Lower | Tank |
| | Flowrate | Flowrate | Flowrate | Flowrate | threshold | threshold | level |
| | | | | | level | level | |

The reversed rules for ‘Tank’, along with the corresponding forward rules stated in propositional logic semantics, are shown in Table III.

TABLE III
Reversed and traditional FFL/BRs for Tank using PL semantics.

| | |
|---|---|
| Traditional | {Mode(tank) = Nominal} → {(State(Supply Fluid(tank)=O)} |
| FFL | {Mode(tank) = Nominal} → {(Store Fluid(tank) = O)} |
| | {Mode(tank) = Overflow} → {(State(Store Fluid(tank)=L))} |
| | {Mode(tank) = Dryout} → {(State(Supply Fluid (tank)=L))} |
| Reversed | {State(SupplyFluid(tank)=O)}→{[Mode(tank)=Nominal] ⊕ |
| FFL | [Mode(tank) = Overflow]} |
| | {State(StoreFluid(tank)=O)}→{[Mode(tank) = Nominal] ⊕ |
| | [Mode(tank) = Dryout]} |
| | {State(StoreFluid(tank)=L)}→{[Mode(tank) = Overflow] ⊕ |
| | [Mode(tank) = Dryout]} |
| | {State(SupplyFluid(tank)=L)}→ {[Mode(tank) = Overflow] ⊕ |
| | [Mode(tank) = Dryout]} |
| Traditional | {{[ L > L_{LTH}] ∧ [L < L_{UTH} ]} ∧ {Q_{oT} = Q_{iT} }} → {Mode(tank) = |
| BRs | Nominal} |
| | {L ≤ L_{LTH}} → {Mode(tank) = Dryout} |
| | {L ≥ L_{UTH}} → {Mode(tank) = Overflow} |
| Reversed | { [Mode(tank) = Overflow] ⊕ [Mode(tank) = Dryout] } → {[{[L |
| BRs | ≤ L_{LTH}] ⊕ [L ≥ L_{UTH}]} ∧ {¬[( L > L_{LTH}) ∧ ( L < L_{UTH} )] ∧ |
| | [Q_{oT}=Q_{iT}] ∧ ¬ [Q_{oT}>Q_{iT}] ∧ ¬ [Q_{oT} < Q_{iT}]}]∨[{[Q_{oT} > Q_{iT}] ⊕ |
| | [Q_{oT}<Q_{iT}]} ∧ {¬ [Q_{oT} = Q_{iT}]} ∧ {[( L > L_{LTH}) ∧ ( L < L_{UTH} )] |
| | \tilde{⊕} [L ≤ L_{LTH}] \tilde{⊕} [L ≥ L_{UTH}] }]} |
| | { [Mode(tank) = Nominal] ⊕ [Mode(tank) = Overflow] } → |
| | {[{ [Q_{oT} = Q_{iT}] \tilde{⊕} [Q_{oT}>Q_{iT}] ⊕ [Q_{oT}<Q_{iT}] } ∧ {¬[L ≤ L_{LTH}] |
| | ∧ [L ≥ L_{UTH}] ∧ ¬ [ ( L > L_{LTH}) ∧ ( L < L_{UTH} ) ] }] ∨[{ [Q_{oT} = |
| | Q_{iT}] \tilde{⊕} [Q_{oT}>Q_{iT}] \tilde{⊕} [Q_{oT}<Q_{iT}] } ∧ { ( ¬ [L ≤ L_{LTH}] ∧ ¬ [L |
| | ≥ L_{UTH}] ∧ [( L > L_{LTH}) ∧ ( L < L_{UTH} )] }] } |
| | { [Mode(tank) = Nominal] ⊕ [Mode(tank) = Dryout] } → {{[L |
| | ≤ L_{LTH}] ⊕ [( L > L_{LTH}) ∧ ( L < L_{UTH} )] } ∧ {¬ [L ≥ L_{UTH}]} ∧ |
| | {[Q_{oT}=Q_{iT}] \tilde{⊕} [Q_{oT}>Q_{iT}] \tilde{⊕} [Q_{oT}<Q_{iT}]} } |

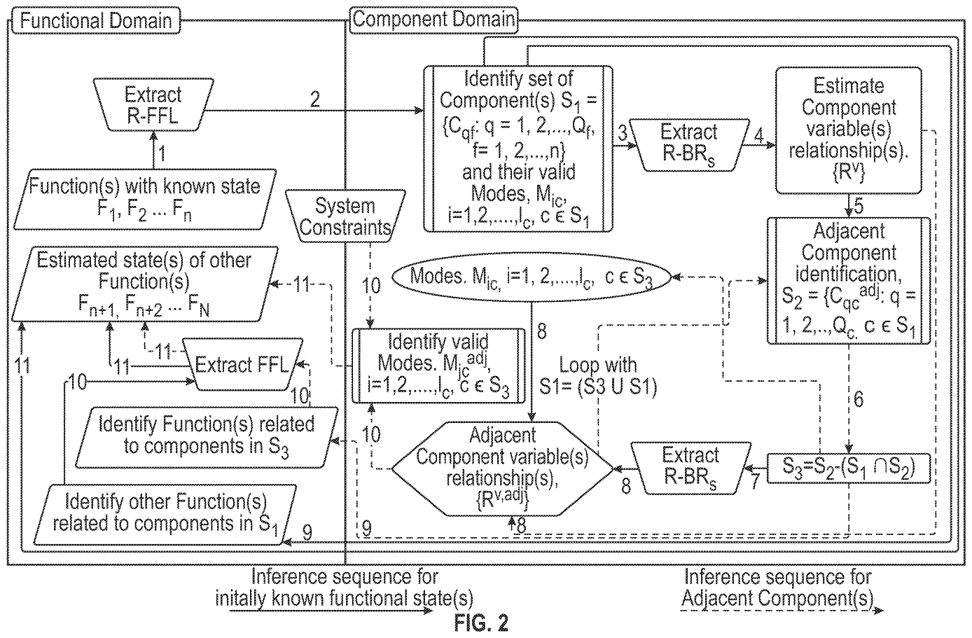

Referring now to FIG. 2, a diagram of the backward failure propagation process disclosed herein is shown, according to some implementations. The overall process can be divided into functional and component domains. The arrows depict the process sequence in the picture, and the numbers on the arrows refer to the process stage. The stages with the same numbers are completed at the same time. The known states of functions(s) (F1, F2, . . . . Fn) are provided as initial information. In the diagram, the notations ‘F,’ ‘C,’ ‘M,’ ‘R^{v},’ and ‘SX’ refer to functions, components, modes of components, variable relations, and sets of components, respectively. The indexes ‘f,’ ‘q,’ ‘i,’, and ‘c,’ identify the index of a function, the index of components related to a given function, the counting index, and the index for components in a set, respectively. Given the information about the component connection and the functions with known states, the step-by-step sequence of the algorithm is as follows.

First, the RFFL(s) are extracted for ‘n’ number of function(s) whose states are known. The set containing these functions is F′⊆F. RFFL(F_{h′}) is given by Eq. 9, F_{h′}∈F′, and ‘h′’ is the index of functions in F′.

Second, the set of relevant components(s), ‘C_{R}’, is generated for each function in F′ by discovering the components associated with their RFFLs. A component, ‘Cᵤ’, from ‘C’ would be included in ‘C_{R}’ if RFFL(F_{h′}) depends on Mode(Cᵤ). The relevant components are identified for each function in ‘F′’ to create the set of components ‘S1’. Where ‘q’ and ‘f’ are the ‘index of relevant components for a function f’ and ‘index for functions’ respectively for S1. Further, for each component in ‘S1’, the component modes are inferred using the RFFLs identified in Step 1. Then the component mode(s) are inferred from the definition of RFFL in Eq. 9, if RFFL(F_{h′}) depends on Mode(C_{q}_{_{f}}):

[(State(F_{h′})=Sₚ)→(Mode(C_{q}_{_{f}})=M_{w})]→(Mode(C_{q}_{_{f}})=M_{w}),

where C_{q}_{_{f}}∈S1 and F_{h′}∈F′. This yields the set for inferred modes of the relevant components, M_{ic}, where, ‘i’ is the index of valid modes for a component and ‘c’ is the index of components in S1.

Third, the RBRs are identified for each component in S1, using Eq. 10:

RBRⱼ_{^{r}} [symbol] (Mode(C_{q}_{_{f}})=M₁)¿ . . . ¿(Mode(C_{q}_{_{f}})=M_{w}))→(OpV?IpV)₁¿ . . . ¿(OpV?IpV)_{b},C_{q}_{_{f}}∈S1,M_{w}∈M

where ‘j^{r}’ is the index for RBRs of a C_{q}_{_{f}}.

Fourth, the RBRs are used to determine the variable relations, ‘R^{V}’, for all the components in S1 at “Step 2”:

R^{V}(C_{qf}) [symbol] [(OpV?IpV)₁¿ . . . ¿(OpV?IpV)ᵥ],

where ‘v’ is the index for types of physical variables for ‘C_{qf}’. Given the mode of a component, the R^{v} is inferred using the component's RBR(s):

{[(Mode(C_{qf})=M₁)¿ . . . ¿((Mode(C_{qf})=M_{w}))→(OpV?IpV)₁¿ . . . ¿(OpV?IpV)ᵥ]∧[(Mode(C_{qf})=M_{w})]} [symbol] {R^{V}(C_{qf})=[(OpV?IpV)₁¿ . . . ¿(OpV?IpV)ᵥ]}

A solid line represents the procedure of dealing with the first set (S₁) of component(s) in FIG. 2. The process for the adjacent components is depicted in FIG. 2 with a trace pattern dash-dot-dot. The details about the inference of variable relations are discussed below.

Fifth, the set (‘S2’) for the adjacent components—an adjacent component is denoted by

$${C}_{qc}^{adj} ,$$

‘q’ and ‘c’ are the indexes of ‘adjacent components connected to c and ‘relevant components,’ respectively—is created using the system diagram by identifying the components connected to the relevant components.

In step six, the adjacent set and the initial set of components are disjointed by eliminating the common components from the adjacent set, creating ‘S3’, S3=S2−(S1∩S2).

At step seven, the RBRs for the adjacent set of components and the modes for these components are identified. From Eq. 10, it is known that:

$${RBR}_{{j}^{r}} = ( ( Mode ( {C}_{qc}^{adj} ) = {M}_{1} ) ¿ … ¿ ( ( Mode ( {C}_{qc}^{adj} ) = {M}_{w} ) ) \to {( OpV ? IpV )}_{1} ¿ … {¿ ( OpV ? IpV )}_{v} , {C}_{qc}^{adj} ∈ S 3 , {M}_{w} ∈ M$$

For ease of reference, lets us write the set of modes M for an adjacent component

$${C}_{qc}^{adj}$$

as

$${M}_{{C}_{qc}^{adj}} .$$

Eighth, ‘R^{V}’ obtained in Step 4 is used for inference of variable relations for the adjacent components,

$$‘ {R}^{V} ( {C}_{qc}^{adj} ) ’ ,$$

which is inferred by finding valid combinations of physical variables (e.g., the combinations which do not contradict the constraints) using the result from Step 4 and RBRs of the adjacent component. For this step, the logic inference needs to be performed individually for each mode of the adjacent component mode. It is known that:

$${R}^{V} ( {C}_{qc}^{} ) = {( {OpV}_{{C}_{qc}} ? {IpV}_{{C}_{qc}} )}_{1} ¿ … {¿ ( {OpV}_{{C}_{qc}} ? {IpV}_{{C}_{qc}} )}_{v}$$

$${R}^{V , adj} ( {C}_{qc}^{adj} ) = {( {OpV}_{{C}_{qc}^{adj}} ? {IpV}_{{C}_{qc}^{adj}} )}_{1} ¿ … {¿ ( {OpV}_{{C}_{qc}^{adj}} ? {IpV}_{{C}_{qc}^{adj}} )}_{v}$$

Based on the physical connection of the relevant and the adjacent components, it can be shown that the input physical variables of the relevant component should be the output physical variables of the adjacent component,

$${OpV}_{{C}_{qc}^{adj}} = {IpV}_{{C}_{qc}} ,$$

then R^{v} becomes:

$${R}^{V} ( {C}_{qc}^{} ) = {( {OpV}_{{C}_{qc}} ? {OpV}_{{C}_{qc}^{adj}} )}_{1} ¿ … {¿ ( {OpV}_{{C}_{qc}} ? {OpV}_{{C}_{qc}^{adj}} )}_{v}$$

From the RBRs in Step 7, for each mode of

$$‘ {C}_{qc}^{adj} ’$$

in

$${M}_{{C}_{qc}^{adj}} : [ ( ( Mode ( {C}_{qc}^{adj} ) = {M}_{w} ) ∧ ( RBR ( {C}_{qc}^{adj} ) ) ] ⊨ {R}^{V} ( {C}_{qc}^{adj} ) , {M}_{w} ∈ {M}_{{C}_{qc}^{adj}} , {C}_{qc}^{adj} ∈ S 3$$

Then, algebraic manipulation of

$${R}^{V} ( {C}_{qc}^{adj} )$$

and R^{V}(C_{qc}) yields:

$${R}^{V} ( {C}_{qc}^{adj} ) = {( OpV ? {IpV}_{{C}_{qc}^{adj}} )}_{1} \text{?} … . \text{?} {( OpV ? {IpV}_{{C}_{qc}^{adj}} )}_{v}$$

Ninth, the functions relevant to the components in ‘S1’ and ‘S3,’ other than the initially known functions, are identified and the set F²′ and F″ are formed, respectively: F²′=F−F′, Fₕ_{^{2′}}∈F²′ iff RFFL(Fₕ_{^{2′}}) depends on Mode(C_{qc}), ‘h²′’ is the index of functions in F²′, and C_{qf}∈S1; and F″=F−F′, F_{h″}∈F″ iff RFFL(F_{h″}) depends on

$$Mode ( {C}_{qc}^{adj} ) ,$$

‘h′’ is the index of functions in F″, and

$${C}_{qc}^{aιij} ∈ S 3.$$

In some cases, it can be beneficial to check all the modes of a component for validity due to the lack of information about the initial state of the system. For example, a component may be under any mode when the mode of the component and the state of the function(s) that serves is not known, while the possibility of having multiple valid modes of a component for a given situation results in branching. However, the branches with invalid ‘R^{V,adj}’ will be truncated. The ‘R^{V,adj}’ are assessed for contradiction with the system constraints, ‘R^{V,Constr}’, to identify the valid component modes for the components in S3:

[Mw,Valid=Mw]↔{[(RV,adj)∧(RV,Constr)]}

where,

$${C}_{qc}^{aιij} ∈ S 3 , {M}_{w} ∈ {M}_{{C}_{qc}^{adj}}$$

which yields the set for inferred modes of the adjacent components M_{ic}^{adj}, where, ‘i’ is the index of valid modes for a component and ‘c’ is the index of components in S3. The system constraints, ‘R^{V,Constr}’, are the expressions comprising of physical variables that describe the limitation engendered by the physics (e.g., the electrical current would be zero without a potential difference) or the constraints that are intended to be a part of the design (e.g., at least one of the two pumps is always working). Moreover, the FFLs for the functions in F²′ and F″ are identified, e.g., the functions served by the components in S1 and S3.

Lastly (e.g., “tenth”), the valid modes of adjacent components ‘M_{ic}^{adj}’ are used with the FFL for the functions in F″ to determine (as for the traditional ISFA:

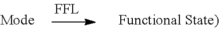

the states of the function(s) served by the adjacent component(s). Similarly, ‘M_{ic}’ with the FFL for the functions in F²′ for the other functions related to the relevant component(s). Then the loop is repeated to update S1 and S3, S1=S3∪S1 and S3=S2−(S1∩S2) until all the components are covered, i.e., S3=Ø.

Example of Inference for the Relevant Component: Consider the following scenario to illustrate the process of inference from component modes to variable relations. Assume that the state of one of the system's functions is known. The modes of relevant components are first deduced from known states of function(s). The ‘Tank’ RFFL, for example, with a known state of ‘Store Fluid’ as ‘Lost,’ implies that the relevant component mode(s) are ‘Overflow’ or ‘Dryout.’ Second, variable relations can be inferred based on the RBRs and the valid mode(s) of the component Tank. For example, starting with RBRs from Table 4, the relations for the modes ‘Overflow’ and ‘Dryout’ can be derived as follows beginning with RBRs from Table 4:

$$\{ [ Mode ( tank ) = Overflow ⊕ Mode ( tank ) = Dryout ] \} \to \{ ( ( [ L \geq {L}_{UTH} ] ⊕ [ L \leq {L}_{LTH} ] ⋀ [ {Q}_{oT} = {Q}_{iT} ] ) ⋁ ( ( [ {Q}_{oT} < {Q}_{iT} ] ⊕ [ {Q}_{oT} > {Q}_{iT} ] ) ⋀ ( [ ( L > {L}_{LTH} ) ⋀ ( L \leq {L}_{UTH} ) ] \tilde{⊕} [ L \leq {L}_{LTH} ] \tilde{⊕} [ L \geq {L}_{UTH} ] ) ) \}$$

Now, a constraint specifying that the level is not in the mid-range and the input flowrate is not equal to the output flowrate is defined. Further, based on the physics, it is known that:

{[(L>L_{LTH})∧(L<L_{UTH})]\tilde{⊕}[L≤L_{LTH}]\tilde{⊕}[L≥L_{UTH}]}

{[Q_{oT}=_{iT}]\tilde{⊕}[Q_{oT}>Q_{iT}]\tilde{⊕}[Q_{oT}<Q_{iT}]}

Solving the constraints with the RBRs:

[Mode(tank)=Overflow]→{[L≥L_{UTH}]}∧{[Q_{oT}>Q_{iT}]∨[Q_{oT}<Q_{iT}]}

[Mode(tank)=Dryout]→{[L≤L_{LTH}]}∧{[Q_{oT}<Q_{iT}]}∨[Q_{oT}>Q_{iT}]}

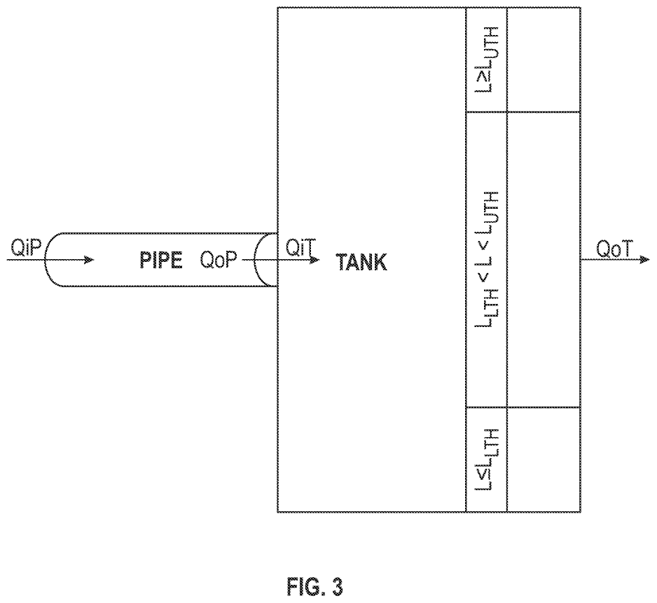

Example of Inference for the Adjacent Component: To demonstrate the inference for variable relations for an adjacent component, let consider that the component ‘Tank’ discussed above is connected to an adjacent component ‘Pipe,’ as shown in FIG. 3. The ‘Tank’ serves two functions: to ‘Store Fluid’ and to ‘Supply Fluid’. The pipe serves the function ‘Transfer Fluid. For the sake of demonstration, assume that ‘Store Fluid’ is ‘Lost’ due to Tank failure and then extend the failure backward to ‘Transfer Fluid.’ The system is constrained by the following physical constraints: flow rates and levels cannot be negative; for tank flowrates, the relationships Q_{oT}=Q_{iT}, Q_{oT}>Q_{iT}, and Q_{oT}<Q_{iT} are mutually exclusive and exhaustive; for the tank level, the relationships L≤L_{LTH}, L≥L_{UTH}, [(L>L_{LTH})∧(L<L_{UTH})]) are mutually exclusive and exhaustive; for the pipe flowrates, the relationships Q_{oP}=Q_{iP}, Q_{oP}<Q_{iP}, and Q_{oP}=0 are mutually exclusive and exhaustive; assuming no leak at the interface, i.e. the flow out of the Pipe is the same as the flow into the tank, Q_{oP}=Q_{iT}; and assuming that we are interested in the worst-case scenarios, i.e. when Q_{oT} ≠Q_{iT}, i.e, Q_{oT}>Q_{iT} while the fluid level is low, and Q_{oT}<Q_{iT} while the fluid level is high.

Solving for the constraints established above, and the RBRs for the Pipe (Table IV), the variable relations for Pipe modes in each branch shown in Table V are obtained.

TABLE IV
Rules for Pipe: FFL, BRs, and RBRs

| BRs | RBRs |
|---|---|
| {Q_{oP} = Q_{iP}} → {[Mode(Pipe) = Nominal]} | {[Mode(Pipe) = Nominal]} → {Q_{oP} = Q_{iP}} |
| {Q_{oP} < Q_{iP}}→{[Mode(Pipe) = Leak]} | {[Mode(Pipe) = Leak]} → {Q_{oP} < Q_{iP}} |
| {Q_{oP} = 0} → {[Mode(Pipe) = Burst]} | {[Mode(Pipe) = Burst]} → {Q_{oP} = 0} |

| | |
|---|---|
| Traditional FFL | IF mode = Nominal, Then Transfer Fluid = Operating |
| | IF mode = Leak, Then Transfer Fluid = Degraded |
| | IF mode = Burst, Then Transfer Fluid = Lost |

TABLE V
Rules for Pipe: FFL, BRs, and RBRs

| Branch1: Overflow (Q_{oT} < Q_{iT}) | Branch2: Dryout (Q_{oT} > Q_{iT}) |
|---|---|
| Pipe mode Nominal given Q_{oT} < Q_{iP} | Pipe mode Nominal given Q_{oT} > Q_{iP} |
| Pipe mode Leak given Q_{oT} < Q_{iP} | Pipe mode Leak given 0 ≤ Q_{iP} ≤ ∞ |
| Pipe mode Burst given Q_{oT} < 0 (invalid) | Pipe mode Burst given 0 ≤ Q_{iP} ≤ ∞ |

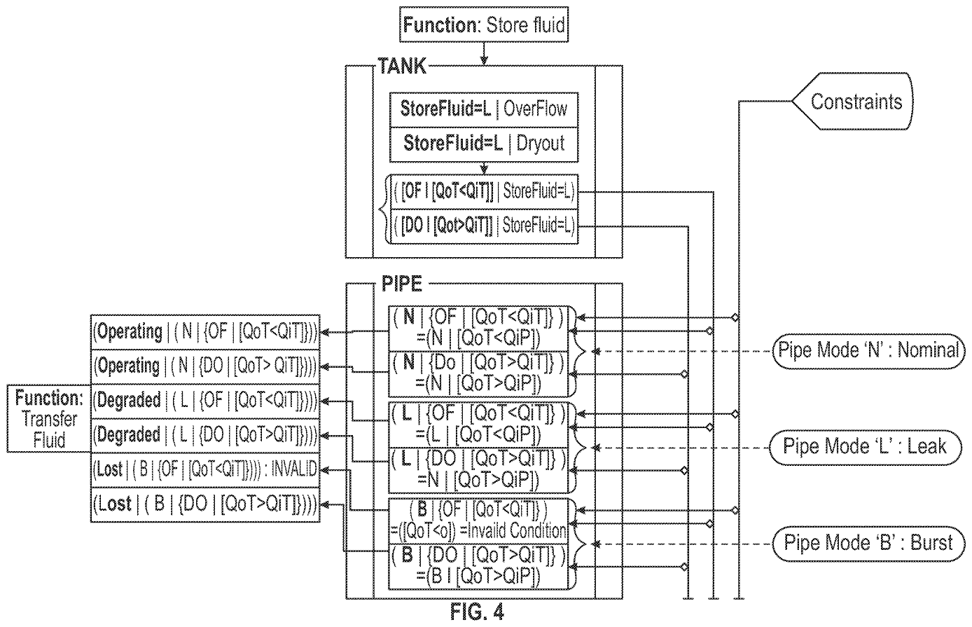

FIG. 4 shows the result of inference of the function ‘Transfer Fluid’ served by the component Pipe, inferred from the failure of Tank's function ‘Store Fluid’. Two branches are obtained based upon the two modes of operation for the component Tank, e.g., ‘Overflow’ and ‘Dryout’. It can be observed that all the functional states are possible for the function ‘Transfer Fluid’ when the tank mode is ‘Dryout’, However, the ‘Transfer Fluid’ cannot be ‘Lost’ in the case of Tank mode ‘Overflow’.

### Probabilistic Augmentation of BLIPS (BLIPS-PA)

As discussed above, for a given initial state of a system, BLIPS generates all possible backward propagation paths that contain the entire state-space (e.g., states of system functions, modes of components, and states of physical variables of the components). One of the features of BLIPS, in contrast to other deductive methods, is the capability to formally prove or disprove the validity of inferred backward sequences. Even though the result generated by BLIPS is an exhaustive collection of failure sequences (e.g., where a sequence includes functional state(s), component modes, and states of physical variables) associated with the failure, a vast list of possible outcomes makes it difficult for the analyst to comprehend the results. An analyst typically seeks to understand the relationship between different failure modes to discriminate sequences with higher relative importance to make effective decisions about the design.

Therefore, to draw conclusions based on the relative importance of the results, a relative weight can be attached to the results of BLIPS in order to improve comprehensibility. In this regard, the results produced by BLIPS can be enhanced using probabilistic augmentation designed to show the impact of the controlled parameter(s) upon the given failure sequence in terms of varying normalized probability of a failure sequence as a function of the probability of the parameter(s). For instance, consider a noticeable failure, such as a car that will not start. This particular failure can be attributed to various underlying causes, including a dead battery, blown fuses, corroded spark plugs, and so on. However, each cause holds a different level of significance with respect to the failure. From a designer's perspective, it is beneficial to study how the likelihood of failure changes in response to the changes in the probability of each cause. Understanding this relationship is important to prioritize the factors contributing to the failure and address them accordingly.

As discussed below, conditional probability of a component mode (e.g., a parameter at the lower level of abstraction in the results produced by BLIPS) can be estimated based on the state of a function (e.g., a high-level parameter). Additionally, a similar conditional probability can be calculated when multiple functional states are associated with a component. This is achieved by using probability theory in conjunction with fuzzy logic to generate fuzzy RFFLs, which takes into account the imprecision in the qualitative definitions of the model. Furthermore, the conditional probability of the lower-level segment of the sequence containing component modes and states of physical variables can be computed. This represents the likelihood of the failure sequence in terms of the parameters being observed by the analyst, given the parameters of the sequence that are assumed to have a certain state, in turn allowing the analyst to see the results of the deductive analysis in terms of the varying probability of the parameters of a failure sequence.

A probabilistic view of the BLIPS results can assist an analyst in making design decisions by observing the impact of various parameters on the system's performance. The design-related decisions include, but are not limited to, setting up a design criterion for system operation to keep certain parameters in a specified range for operation, introducing monitoring instrumentation, providing redundancy and/or diversity for the limiting functions and/or components, etc.

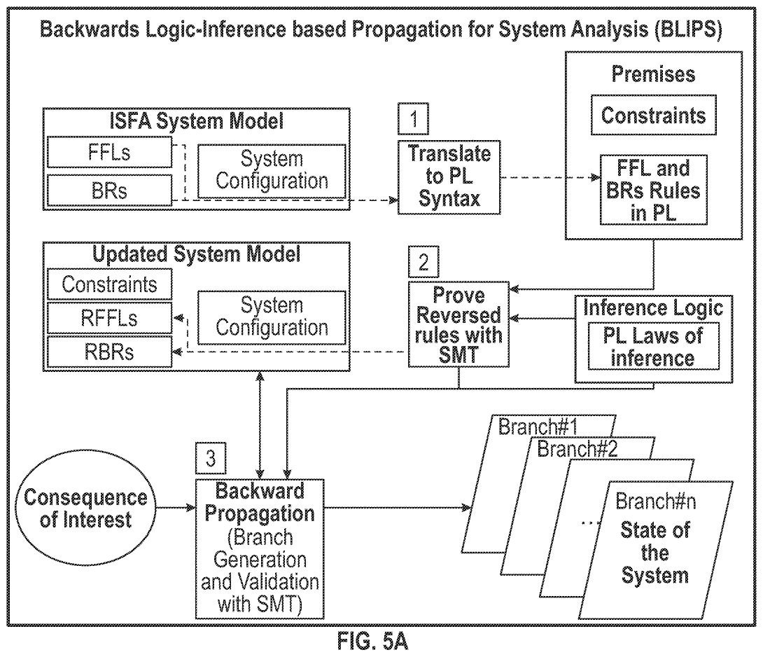

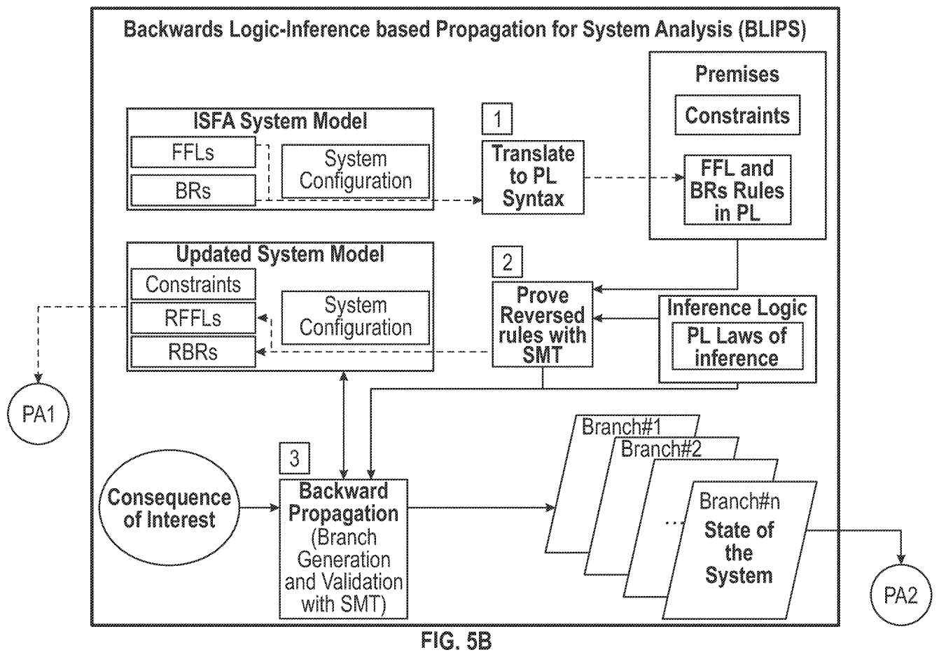

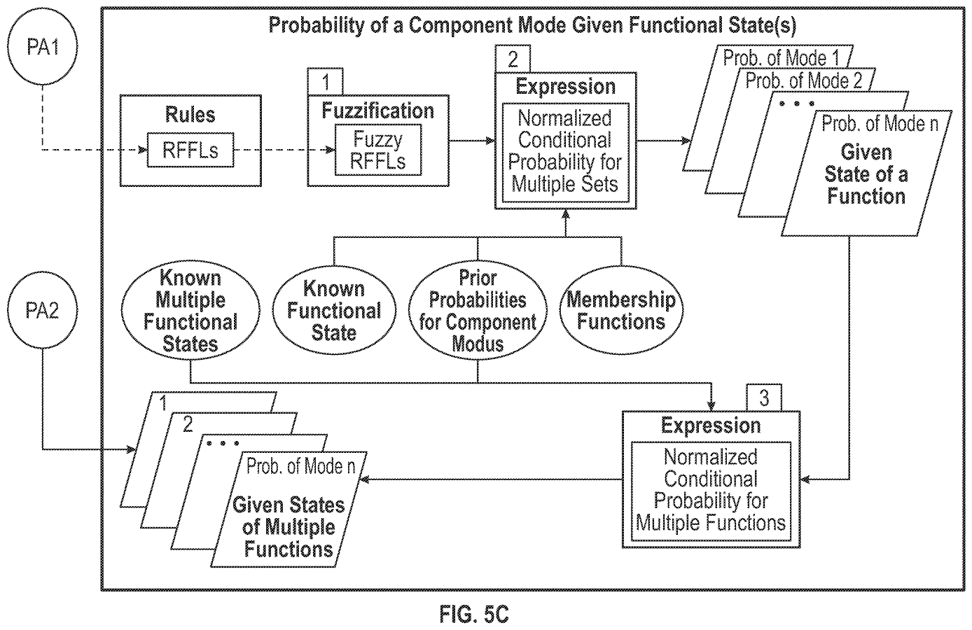

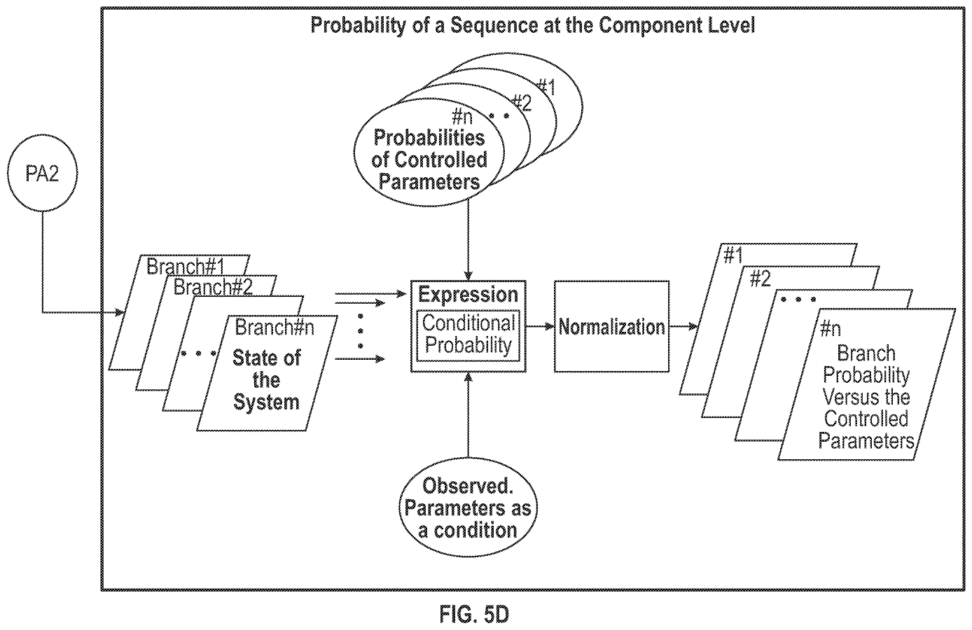

As discussed above, BLIPS generates all possible backward propagation paths that contain the entire state-space (e.g., system functions, modes of components, and states of physical variables associated with the components). BLIPS is a deductive inference method that utilizes the system's behavioral and functional models, e.g., used in ISFA, along with rules of PL. A brief label-wise overview of the BLIPS methodology is shown in FIG. 5A. The BLIPS framework employs ISFA's FFL and BRs, but in a reversed manner. Because the ISFA rules are defined using if-then statements, to derive the reversed rules of ISFA formally, the ISFA rules are initially translated into PL syntax. This translation enables mathematical manipulation and subsequent derivation of the reversed rules. Then, the derivation of the reversed rules is carried out using PL's laws of inference. The premises for the derivation comprises of FFL and BRs in PL syntax and a set of system constraints. The constraints cater for the logical and physical limitations of the system, e.g., flows and levels cannot be less than zero, component modes are exclusive, etc. The RFFL and RBRs are proven using SMT based on the given premises. This process results in an updated model of the system that includes the reversed rules, constraints, and system configuration.

Backward propagation is conducted by assuming an initial condition, which represents the desired consequence of the system. This initial condition can include functional states, component modes, states of physical variables, or a combination of these parameters. The assumed condition is then propagated backward through the system's configuration. At each node of the propagation, valid system parameters (e.g., functional states, component modes, and states of physical variables) are inferred with the engine of logic inference, which is based upon the system's functional and behavioral model governed by the physics of the system and the laws of PL to formally prove or disprove the conclusion utilizing a SMT solver. The determination of valid parameters is based on the premises derived from the updated system model, which includes RFFLs, BRs, and constraints. Each set of valid parameters is referred to as a branch, and all the valid branches (e.g., which are unique) are represented in the results.

BLIPS allows managing the state space by setting the initial states of known functional states, component(s) modes, and states of physical variables to the most expected values or the values of interest. This allows a user to generate the branches for system parameters of interest and curtail the rest of them, or the analysis can be divided into modules by creating multiple scenarios of interest and evaluating them separately. This does not mean that it is necessary to perform a modular analysis, but it is merely the choice of the user to select the span of analysis. Besides the issue regarding state space, due to the advantageous nature of the methodology, which involves processing one step of propagation at a time, the computational load for the method cannot be equivalent to the methods that solve the entire system at once or involve complex mathematical processes like matrix-inversion.

Methodology for PA: BLIPS aims to identify all the possible deductive sequences for a given system condition in terms of functional states, component modes, and states of physical variables and then prove the sequences for their validity. The sequences are referred to as branches of the backward failure analysis as they stem from a given initial assumption. Due to the large number of branches generated during such analysis—which is expected for any deductive analysis—adding weight in terms of probability to the branches can make the results more comprehensible and assist an analyst in making more informed decisions. This approach is referred to herein as probabilistic augmentation of BLIPS; in short, BLIPS-PA.

BLIPS utilizes the functional and behavioral models used for ISFA. As shown in FIG. 5B, the ISFA model comprises of the rules (FFL, BRs) and the system configuration. The configuration refers to the structure of a system, e.g., SLDs for electrical systems, and P&IDs for mechanical systems etc. First, the rules are translated into PL syntax for mathematical manipulation. Second, the translated rules are reversed for the deductive analysis. In order to derive the reversed rules, a set of system constraints is introduced, which caters for the logical and physical limitations of the system. e.g., flows and levels cannot be less than zero, component modes are exclusive, etc.

In some implementations, the reversed rules (RFFLs) are derived using the PL laws of inference, while the FFL, BRs, and constraints serve as the premises for the proof. At this point, the updated system model comprises of RFFLs, RBRs, constraints, and system configuration. Then, an assumed initial state of the system is traversed backwards to logically infer the states of unknown parameters of the system using the updated system model. Typically, an initial condition is a state of a function; however, it may also be modes of component(s) and/or state of physical variables or a combination of all three elements. FIGS. 5C and 5D show the steps for PA of BLIPS; the two sub-methods are linked to FIG. 5B with the connectors PA1 and PA2.

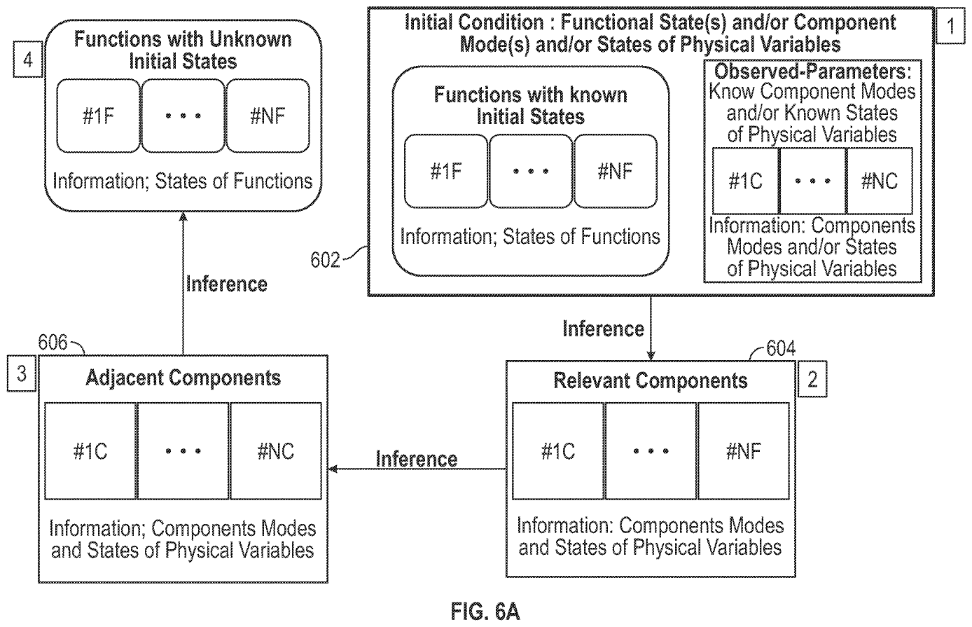

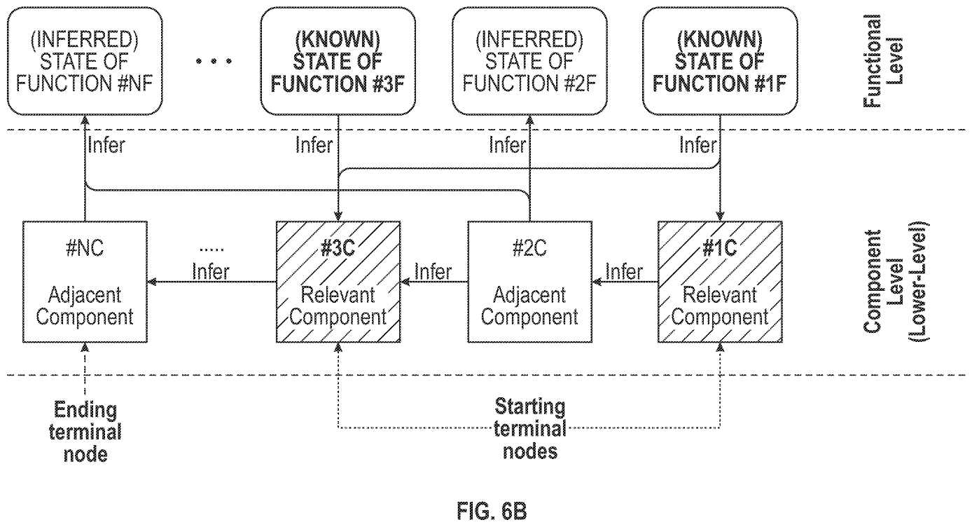

The branches obtained from BLIPS contain information about all system elements, which include functional states, component modes, and states of physical variables. A generic representation of a branch is provided in FIG. 6A. A branch comprises of the initially known elements and the inferred elements. At 602, the initial state of the system refers to the following elements individually or their combination: functions with known states, known modes of components, and states of physical variables. The state of a function is assumed to be ‘Operating’, ‘Failed’, or ‘Degraded’ etc.—the system model defines the possible states for a function—as an initial condition by the user; usually, for safety analysis, safety-critical function(s) are assumed to be in a failed state. Similarly, the modes of certain components and the states of some physical variables can also be included in the initial condition, as deemed necessary by the user.

Depending upon the initially available information, the modes of components are inferred based on known functional states and/or states of physical variables. Relevant components 604 are the components directly associated with the functions whose functional states are known and the components whose modes and/or state(s) of physical variable(s) are known. The components connected to the relevant components are adjacent components 606. The states of physical variables are inferred based on functional states, component modes, and other physical variables. The branches cover both abstraction levels, functional and component. FIG. 6B shows an example of the propagation view of a branch obtained with multiple known functional states. The functions #1F and #NF are associated with two relevant components each, namely #1C and #3C for function #1F, and #2C and #NC for function #NF. The state of adjacent component #2C is inferred based on the relevant components #1C and #3C.

The methodology described herein is used for determining the probability of a component mode when the information about states of directly associated functions is available. This is a conditional probability of a specific component mode when a state of a function is known. This conditional probability is calculated by fuzzified RFFL. The process to find the component mode's probability given a functional state is explained label-wise as shown in FIG. 5C, as introduced above.

First, a fuzzification of RFFLs from the updated system model is performed. The RFFLs are obtained from the updated system model for BLIPS (connector PA1); the RFFLs are the fuzzy sets. The members of a fuzzy set are the sub-RFFLs; sub-RFFLs are extracted from RFFLs and have a degree of membership towards the RFFL. The applicable fuzzy RFFL is utilized to compute the probability of a component mode given a functional state. The calculation utilizes the values of the membership functions, as well as a prior probability for the sub-RFFLs. These values can be obtained from the operational history of a similar system, design specifications, regulatory requirements, or an expert's opinion in case of unavailability of data.

Second, even the simplest of systems is expected to have more than one RFFL. An expression for the probability is derived below that caters for the existence of multiple fuzzy sets. The probability obtained using the expression gives the probability of a component mode given a functional state. However, if a component is associated with multiple functions, the probability of the component mode given states of those functions becomes a special case due to the dependence of the functions on each other. Lastly, an expression for the component mode given multiple functional states is also derived below. The derived expression is a function of the functional states and the prior probabilities of component modes.

The probability for the component-level of a branch (e.g., the levels in a branch are shown in FIG. 5C) is the joint probability of the components' modes and the states of physical variables in the branch. Inference begins at the node(s) at which the states of physical variable(s) are known, referred to as starting terminal node. The last node inferred in the process of propagation, which does not contribute to further inference is referred to as the ending terminal node. An example of the terminal nodes is shown in FIG. 6B, where the inference begins at components #1C and #3C based on modes of the components inferred from functions #1F and #3F. Further, component #NC does not contribute to a further inference; hence it is the ending terminal node.

In a branch obtained from BLIPS, the branch parameters from the lower-level (e.g., component modes and states of physical variables) are an assertion—for example, a probability of 1—because BLIPS is a method for deductive analysis which generates the possible branches (e.g., which are exhaustive and mutually exclusive) that lead to the assumed condition of a system. However, to investigate the influence of the branch's parameter(s) on branch's probability, it is beneficial to treat the parameters' probabilities as variables. These probabilities can be represented by either a point-probability or an interval of probabilities.

To evaluate the probability of the sequence of parameters in the lower level of a branch, the controlled parameters and the observable parameters are identified. The controlled parameters are the parameters of the branch whose impact is being studied on the probability of the branch. These parameters can be state(s) of variable(s) and/or mode(s) of component(s). To derive the expression of probability, which will be a conditional probability, some parameters serve as conditions and will be assigned a probability of one (1) because they are observable parameters. These parameters are known as observable parameters; the term “observable” implies that the state of these parameters can be observed or measured, ensuring certainty of their state. Here onwards, the physical variables of a sequence which are declared as observable parameters are called observed-variables. Similarly, the modes are called observed-modes. And, if both modes and physical variables can be observed, together they are referred to as observed-modes-variables of the branch.

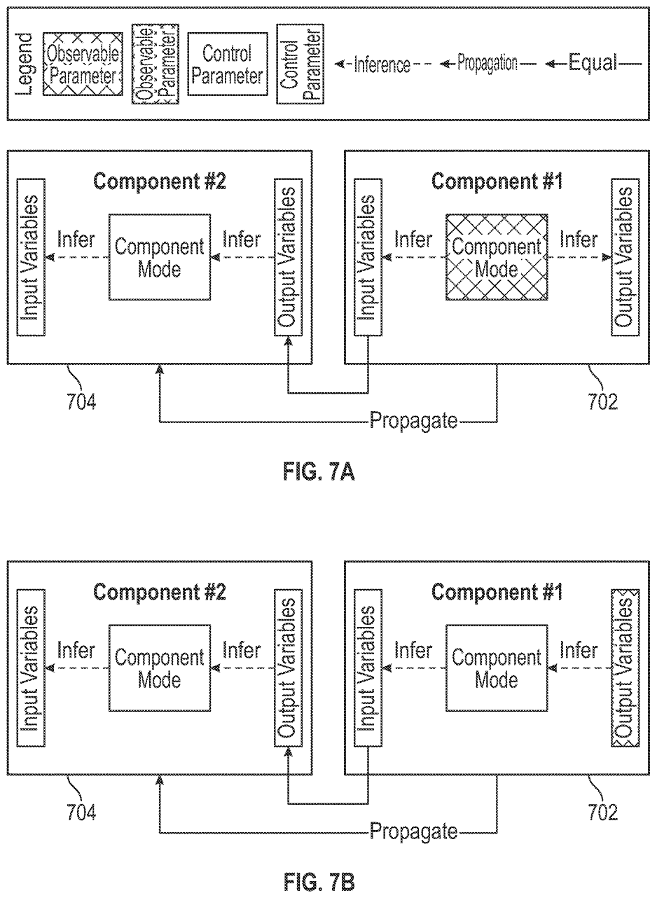

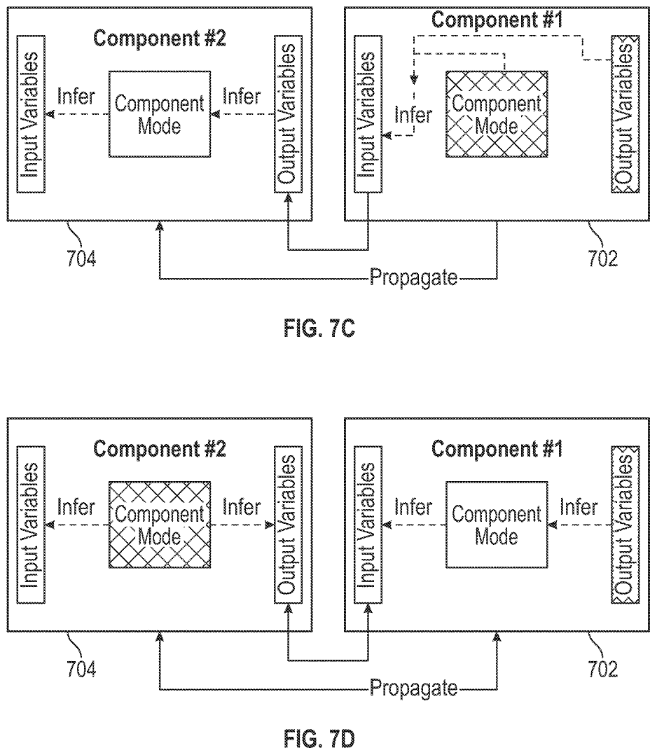

FIG. 7A shows an example of observed-mode, wherein the mode of component 702 (“Component #1”) is declared as an observable parameter; hence the states of physical variables at the output and the input of the component are inferred based on the observed-mode and the parameters of component 704 (“Component #2) are inferred from component 704. FIG. 7B shows an example of observed-variable, where the valid modes of component 702 are inferred from the states of physical variables at the output of the component, and the states of physical variables at the input of the component are inferred from the mode of the component given the states of physical variables at the output. FIGS. 7C and 7D are examples of observed parameters comprising of both observed-mode and observed-variable.

In the first example, states of physical variables at the input of component 702 are inferred from the mode of the component and states of physical variables at the output of the component. Subsequently, the parameters of component 704 are inferred from the states of physical variables at the input of component 702. For the second example, the observed parameters are states of physical variables at the output of component 702 and mode of component 704. In this case, the inference is made in both directions, the valid states of physical variables at the input of component 702—which are the same as the states of physical variables at the output of component 704—are inferred based on parameters from component 702 and component 704. For component 704, on the mode of component and modes of component given the states of physical variables at the output of the component for component 704.

The concept of evidence-based-independence is used to calculate probability at the component level. This concept stems from the fact that inference of the parameters of a component is dependent on the parameters associated with the components (states of physical variables and mode), and on the states of the physical variables of the neighboring component which are common between the two components (where these common variables are established truth and they dictate the inference for the next component). Therefore, the inferred parameters of a component can be considered independent from the parameters of the neighboring components, other than the common parameters between the component under consideration and the immediate neighboring component(s). For example, the mode of a Tank is inferred when the output flow of the tank has already been established to be higher than zero, based on a neighboring component that is connected to the output of the Tank. The mode of the Tank in this situation is limited to either Nominal or Overflow but cannot be Dryout.

The observed parameters are the basis of inference that propagates the evidence through the system. The dependence on the observables is conserved within the branch being analyzed, because the inference from one component to the next, inherently carries the influence of all the previous nodes. The developed probability expression aims to demonstrate how the controlled parameter(s) affect a specific failure sequence by examining the changing normalized probability of the failure sequence based on the varying probability of the controlled parameter(s). Since all branches obtained from BLIPS lead to a single system state, the system's state which was the assumed initial condition for the analysis; each branch's probability is normalized in relation to all other branches to obtain an easily understandable numerical value that represents the relative importance of the branch for the initial condition. As shown in FIG. 5D, the expression(s) for conditional probability is developed using the branch(es) obtained from BLIPS. The computation is carried out by setting the probabilities of the observable parameters to ‘1’ and user-defined probabilities for the controlled parameters. The result of this exercise is a multidimensional relationship between the probability of the branch and the controlled parameters.

Fuzzification of RFFL: The fuzzification of RFFL is accomplished by utilizing a membership function that represents an expert's opinion. As discussed above, the degree of membership of modes of a component is defined by fuzzifying the RFFLs. It is reiterated that each RFFL relates a state of a function with the modes of a component. The inference made from a RFFL provides the mode of a component. This inference has a fuzzy nature, as the same resulting mode can be obtained via two different inferences. This aspect is captured by fuzzy RFFLs. Further, the modes of a component are mutually exclusive and exhaustive, which means that a component can only assume a single mode out of the combination outlined in the RFFL for a given functional state. Therefore, one RFFL can be seen as a fuzzy set of multiple logic statements mapping a state of a function onto a mode of a component. These sub-RFFLs of a RFFL are mutually exclusive to each other, and they are members of the fuzzy sets.

A fuzzy set is denoted by adding the accent, ‘~,’ on the set's name. For instance, [symbol] (F_{h′}), refers to the fuzzy set of reversed functional failure logic of the function, ‘F_{h′}’. ‘k^{r}’ refers to the functional state for which RFFL is defined, and ‘h′’ is the index of functions with known states. For example, the Tank has four fuzzy sets for the two functions, i.e. [symbol] _{Operating}(StoreFluid), [symbol] _{Lost}(StoreFluid), [symbol] _{Operating}(SupplyFluid), and [symbol] _{Lost}(SupplyFluid). Mathematically,

$$\text{?} ( {F}_{{h}^{′}} ) = \{ \begin{matrix}( {sub}_{1} {RFFL}_{{k}^{r}} ( {F}_{{h}^{′}} ) , {m}_{\text{?} ( {F}_{{h}^{′}} )} ( {sub}_{1} {RFFL}_{{k}^{r}} ( {F}_{{h}^{′}} ) ) ) , \\ ( {sub}_{2} {RFFL}_{{k}^{r}} ( {F}_{{h}^{′}} ) , {m}_{\text{?} ( {F}_{{h}^{′}} )} ( {sub}_{2} {RFFL}_{{k}^{r}} ( {F}_{{h}^{′}} ) ) ) , \\ … … , ( {sub}_{B} {RFFL}_{{k}^{r}} ( {F}_{{h}^{′}} ) , {m}_{\text{?} ( {F}_{{h}^{′}} )} ( {sub}_{B} {RFFL}_{{k}^{r}} ( {F}_{{h}^{′}} ) ) ) ,\end{matrix}$$

where ‘B’ is the total number of sub-RFFLs for the given RFFL, [symbol] _{(F}_{_{h′}}₎(sub_{b}RFFLₖ_{^{r}}(F_{h′})) is the membership function of ‘sub_{b}RFFL_{K}_{^{r}}(F_{h′})’ towards the fuzzy set [symbol] (F_{h′}), where ‘b’ is the index of sub-RFFL. For example:

[symbol]

_{Lost}(StoreFluid)={(sub₁RFFL_{Lost}(StoreFluid),1),(sub₂RFFL_{Lost}(StoreFluid),0.7)}

where,

sub₁RFFL_{Lost}(StoreFluid):={State(StoreFluid(tank):=L)}→{[Mode(tank):=Overflow]}

sub₂RFFL_{Lost}(StoreFluid):={State(StoreFluid(tank):=L)}→{[Mode(tank):=Dryout]}.

Normalized Probability for Members of Fuzzy Sets: First, an expression for the probability, P(x∈Ã; m_{Ã}(x)), of an outcome of an experiment ‘x’ belonging to the fuzzy set ‘Ã,’ given the membership function ‘m_{Ã}(x)’ which represents the outcome's degree of membership towards the fuzzy set, is defined. This expression for probability maps to the problems contemplated herein as:

P(x∈Ã;m_{Ã}(x))≡P(sub_{b}RFFLₖ_{^{r}}(F_{h′})∈ [symbol] (F_{h′}); [symbol] _{(F}_{_{h′}}₎(sub_{b}RFFLₖ_{^{r}}(F_{h′})))

This equation represented the probability of the inferred component mode from a sub-RFFL (e.g., when sub-RFFL's membership is provided) being the valid mode for the RFFL of the given functional state. It is worth noting that this probability is based on the likelihood (membership) of a sub-RFFL belonging to a fuzzy set; therefore, the sum of the probabilities for all the cases does not necessarily add to ‘1’. In order to make the information more intuitive, an expression for normalized probability is adopted. To use the fuzzified RFFLs in the framework of probability theory, the probability of ‘x’ belonging to the fuzzy set ‘Ã is represented as:

$$P ( x ∈ \tilde{A} ; {m}_{\tilde{A}} ( x ) ) = [ \frac{L ( x ∈ \tilde{A} , {m}_{\tilde{A}} ( x ) ) P ( x ∈ \tilde{A} )}{L ( x ∈ \tilde{A} , {m}_{\tilde{A}} ( x ) ) P ( x ∈ \tilde{A} ) + L ( x ∉ \tilde{A} , {m}_{\tilde{A}} ( x ) ) P ( x ∉ \tilde{A} )} ]$$

On the right hand side, ‘L( )’ stands for likelihood, ‘P( )’ stands for prior probability, and ‘m_{Ã}(x)’ is the degree of membership of ‘x’ towards ‘Ã’. On the left-hand side, ‘P(;)’ stands for the probability of a member belonging to a fuzzy set given the membership function. For the problem under consideration, ‘x’ represents a sub-RFFL and ‘Ã’ corresponds to the fuzzy RFFL set.

Multiple fuzzy RFFL sets are highly likely to exist. For example, [symbol] _{Lost}(StoreFluid) and [symbol] _{Operating}(StoreFluid) are two out of the four fuzzy sets for “Tank” in the example being discussed. By using, P(x∈Ã)=1−P(x∈Ã), L(x∈Ã,m_{Ã}(x)=m_{Ã}(x), and L(x∈Ã,m_{Ã}(x))=1−m_{Ã}(x), the normalized probability can be obtained as:

$$P ( {sub}_{b} {RFFL}_{{k}^{r}} ( {F}_{{h}^{′}} ) ∈ \text{?} ( {F}_{{h}^{′}} ) ; {m}_{\text{?} ( {F}_{{h}^{′}} )} ( {sub}_{b} {RFFL}_{{k}^{r}} ( {F}_{{h}^{′}} ) ) ) = ( \frac{{m}_{\text{?} ( {F}_{{h}^{′}} )} ( {sub}_{b} {RFFL}_{{k}^{r}} ( {F}_{{h}^{′}} ) ) P ( {sub}_{b} {RFFL}_{{k}^{r}} ( {F}_{{h}^{′}} ) ∈ \text{?} ( {F}_{{h}^{′}} ) )}{{\sum }_{\tilde{p}} {m}_{\tilde{p}} ( {sub}_{b} {RFFL}_{{k}^{r}} ( {F}_{{h}^{′}} ) ) P ( {sub}_{b} {RFFL}_{{k}^{r}} ( {F}_{{h}^{′}} ) ∈ \tilde{p} )} ) {( {\sum }_{{b}^{′}} \frac{{m}_{\text{?} ( {F}_{{h}^{′}} )} ( {sub}_{{b}^{′}} {RFFL}_{{k}^{r}} ( {F}_{{h}^{′}} ) ) P ( {sub}_{{b}^{′}} {RFFL}_{{k}^{r}} ( {F}_{{h}^{′}} ) ∈ \text{?} ( {F}_{{h}^{′}} ) )}{{\sum }_{\tilde{{p}^{′}}} {m}_{\tilde{{p}^{′}}} ( {sub}_{b} {RFFL}_{{k}^{r}} ( {F}_{{h}^{′}} ) ) P ( {sub}_{b} {RFFL}_{{k}^{r}} ( {F}_{{h}^{′}} ) ∈ \tilde{{p}^{′}} )} )}^{- 1}$$

where \tilde{p} and \tilde{p}′ are the indexes of fuzzy sets (note that these indexes cover all the fuzzy sets of a function), and b′ is the index of members of the sets. Moreover, as discussed earlier, ‘x’ represents a sub-RFFL and ‘Ã’ corresponds to the fuzzy RFFL set.

The implication connective of the propositional logic, represented by the → symbol, means that if the proposition on the left side is true, the proposition on the right-hand side has to be true. Further, a sub-RFFL, which is a propositional statement that implies a mode of a component from a functional state, being a member of a fuzzy RFFL (e.g., sub_{b}RFFLₖ_{^{r}}(F_{h′})∈ [symbol] ₖ_{^{r}}(F_{h′})) means that the component mode is the member of a fuzzy RFFL given that the proposition about the functional state is true. Therefore, the left-hand-side of the previous equation, while knowing the state of the function and the degree of membership for the mode of component towards the state of function, can be represented as:

P(sub_{b}RFFLₖ_{^{r}}(F_{h′})∈ [symbol] (F_{h′}); [symbol] _{(F}_{_{h′}}₎(sub_{b}RFFLₖ_{^{r}}(F_{h′})))=P(Mode(component)|State(function)

It may be noted that the sub-RFFLs are propositional logic statements (propositions), where the mode(s) of a component are implied by the state of a function. For example, if the proposition defining the state of the function is true, then the implied mode(s) must hold true. Therefore, the probability of inference from a sub-RFFL is the conditional probability of the mode(s) of components given the state of a function.

Probability of the component mode given multiple relevant functional states: Above, an expression has been developed to calculate the probability of a mode of a component given a functional state. To account for the interdependence of functions associated with a component, the probability of a component mode given multiple relevant functional states should be formulated. This is particularly relevant when dealing with components that have multiple associated functions. Therefore, an expression for the conditional probability for a component mode given the relevant functions of the component is derived as follows:

$$\begin{matrix}P ( ( Mode ( {C}_{{u}^{′}} ) = {M}_{w} ) \vert {⋂}_{{h}^{′}} State ( {F}_{{h}^{′}} ) \\ = {S}_{p} ( {F}_{{h}^{′}} ) ) , {C}_{{u}^{′}} ϵ {𝒞}_{R} , {M}_{w} ϵ ℳ , ( F ϵ {ℱ}^{′} ) and ( {ℱ}^{′} ⊆ ℱ ) , S ϵ 𝒮 , \\ iff {F}_{{h}^{′}} is dependent on {C}_{{u}^{′}}\end{matrix}$$

where, C, [symbol] _{R}, M, and [symbol] refers to a component, a set of relevant components (components associated with the functions in the condition), a mode of a component, and a set of modes of a component, respectively. F, S, [symbol] , [symbol] , and [symbol] represent a function, the state of a function which is specific to each F_{h′}, set of states of a function, set of all the functions in the system, and the set of functions with known conditions, respectively. The indexes u′, w, h′, p are the indexes for components in [symbol] R, modes of a component in [symbol] , functions in [symbol] , and states of a function in [symbol] , respectively.

From this expression, the normalized probability over all the modes of a component can be derived as:

$$P ( {M}_{{M}_{w}}^{{C}_{{u}^{′}}} \vert {⋂}_{{h}^{′}} {S}_{{S}_{p}}^{{F}_{{h}^{′}}} ) = \frac{( {\prod }_{{h}^{′}} [ \frac{P ( {M}_{{M}_{w}}^{{C}_{{u}^{′}}} \vert {S}_{{S}_{p}}^{{F}_{{h}^{′}}}}{P ( {M}_{{M}_{w}}^{{C}_{{u}^{′}}} )} ] ) P ( {M}_{{M}_{w}}^{{C}_{{u}^{′}}} )}{{\sum }_{w ′} ( ( {\prod }_{{h}^{′}} [ \frac{P ( {M}_{{M}_{w}}^{{C}_{{u}^{′}}} \vert {S}_{{S}_{p}}^{{F}_{{h}^{′}}}}{P ( {M}_{{M}_{w}}^{{C}_{{u}^{′}}} )} ] ) P ( {M}_{{M}_{w}}^{{C}_{{u}^{′}}} ) )}$$

Probability calculation at the component level: The parameters in the lower level of a branch include modes of components and states of physical variables. The physical variables at the output side (following the system's configuration, e.g., in the forward direction) of a component and the input side of a component (see FIGS. 7A-7D) are referred to as output physical variables and input physical variables, respectively. These parameters can be defined mathematically as: a set

$${𝒞}_{B}^{′}$$

contains the components of the branch for whose associated physical variables (either on the input or the output side of a component) are observed-variables; set

$${ℳ}_{B}^{′}$$

contains the modes for each component in

$${𝒞}_{B}^{′} ;$$

a set

$${𝒱}_{o}^{′ B}$$

contains the output physical variables (OpV) for the components in

$${𝒞}_{B}^{′}$$

### A set

$${𝒮}_{B}^{′}$$

is the set of states for each physical variable in

$${𝒱}_{o}^{′ B} .$$

Sets [symbol] _{B}, [symbol] _{B},

$${𝒱}_{o}^{B} ,$$

and [symbol] _{B} are the corresponding sets for the unobserved parameters. Note that OpV are the physical variables at the interface between the components, e.g., they are output from the previous component(s) and input to the next component(s) when the system is traced in the forward direction.

In the case of terminal components, which are not connected to other components on one side (acyclic systems), the physical variables on the input side are called input physical variables. A set

$${𝒱}_{i}^{B}$$

contains the input physical variables (IpV) for the terminal components of [symbol] _{B} whose input does not interface with any component of the system being analyzed. IpV represents the output from another system or subsystem (input from outside the system). They are inferred by establishing the modes of all the preceding components. However, these physical variables are different from other physical variables (associated with the preceding components) in the sense that they are not bounded by the mode of the component which is producing them as an output because that component is not a part of the system being observed.

The conditional probability is written as per the definition,

$$P ( A \vert B ) = \frac{P ( A ⋂ B )}{P ( B )}$$

is derived as:

$$\begin{matrix}P ( ( [ {⋂}_{{u}_{b}} ( {M}_{{M}_{{w}_{b}}}^{{C}_{{u}_{b}}} ) ] ⋂ [ {⋂}_{{u}_{b}^{′}} ( {M}_{{M}_{{w}_{b}^{′}}}^{{C}_{{u}_{b}^{′}}} ) ] ⋂ [ {⋂}_{{ov}_{b}} ( {S}_{{S}_{{p}_{b}}}^{{OpV}_{{ov}_{b}}} ) ] \\ ⋂ [ {⋂}_{{iv}_{b}} ( {S}_{{S}_{{p}_{b}}}^{{IpV}_{{iv}_{b}}} ) ] ) \vert [ {⋂}_{{ov}_{b}^{′}} ( {S}_{{S}_{{p}_{b}^{′}}}^{{OpV}_{{ov}_{b}^{′}}} ) ] ) \\ = P ( {⋂}_{{u}_{b}} ( {M}_{{M}_{{w}_{b}}}^{{C}_{{u}_{b}}} ) ) P ( {⋂}_{{u}_{b}^{′}} ( {M}_{{M}_{{w}_{b}^{′}}}^{{C}_{{u}_{b}^{′}}} ) ) P ( {⋂}_{{iv}_{b}} ( {S}_{{S}_{{p}_{b}}}^{{IpV}_{{iv}_{b}}} ) )\end{matrix}$$

where, u_{b}, w_{b}, ov_{b}, iv_{b}, and p_{b}, are the indexes of the components in [symbol] _{B}, modes in [symbol] _{B}, physical variables in

$${𝒱}_{o}^{B} ,$$

physical variables in

$${𝒱}_{i}^{B} ,$$

and states of physical variables in [symbol] _{B}, respectively. And u′_{b}, w′_{b}, ov′_{b}, and p′_{b}, are the indexes of the components in [symbol] ′_{B}, modes in [symbol] ′_{B}, physical variables in

$${V}_{o}^{′B} ,$$

and states of variable in [symbol] ′_{B}, respectively.

For each of the three terms on the right-hand side, the following can be assumed: independence between the modes of different components, the output physical variables of different components, and the input physical variables of different components. This assumption stems from the idea of evidence-based-independence, stating that the parameters of a component are independent from the parameters of a neighboring component, unless the parameters are common between the two components. An example of common parameters between two components is the output physical variable of one component being the input of the other component. Using the assumption of independence:

$$\begin{matrix}P ( ( [ {⋂}_{{u}_{b}} ( {M}_{{M}_{{w}_{b}}}^{{C}_{{u}_{b}}} ) ] ⋂ [ {⋂}_{{u}_{b}^{′}} ( {M}_{{M}_{{w}_{b}^{′}}}^{{C}_{{u}_{b}^{′}}} ) ] ⋂ [ {⋂}_{{ov}_{b}} ( {S}_{{S}_{{p}_{b}}}^{{OpV}_{{ov}_{b}}} ) ] \\ ⋂ [ {⋂}_{{iv}_{b}} ( {S}_{{S}_{{p}_{b}}}^{{IpV}_{{iv}_{b}}} ) ] ) \vert [ {⋂}_{{ov}_{b}^{′}} ( {S}_{{S}_{{p}_{b}^{′}}}^{{OpV}_{{ov}_{b}^{′}}} ) ] ) \\ = [ {\prod }_{{u}_{b}} P ( {M}_{{M}_{{w}_{b}}}^{{C}_{{u}_{b}}} ) ] [ {\prod }_{{u}_{b}^{′}} P ( {M}_{{M}_{{w}_{b}^{′}}}^{{C}_{{u}_{b}^{′}}} ) ] [ {\prod }_{{iv}_{b}} P ( {S}_{{S}_{{p}_{b}}}^{{IpV}_{{iv}_{b}}} ) )\end{matrix}$$

Similarly, the following expression can be obtained for the initial condition with observed-modes:

$$\begin{matrix}P ( ( [ {⋂}_{{u}_{b}} ( {M}_{{M}_{{w}_{b}}}^{{C}_{{u}_{b}}} ) ] ⋂ [ {⋂}_{{ov}_{b}^{′}} ( {S}_{{S}_{{p}_{b}^{′}}}^{{OpV}_{{ov}_{b}^{′}}} ) ] ⋂ [ {⋂}_{{ov}_{b}} ( {S}_{{S}_{{p}_{b}}}^{{OpV}_{{ov}_{b}}} ) ] \\ ⋂ [ {⋂}_{{iv}_{b}} ( {S}_{{S}_{{p}_{b}}}^{{IpV}_{{iv}_{b}}} ) ] ) \vert [ {⋂}_{{u}_{b}^{′}} ( {M}_{{M}_{{w}_{b}^{′}}}^{{C}_{{u}_{b}^{′}}} ) ] ) = [ {\prod }_{{u}_{b}} P ( {M}_{{M}_{{w}_{b}}}^{{C}_{{u}_{b}}} ) ] [ {\prod }_{{iv}_{b}} P ( {S}_{{S}_{{p}_{b}}}^{{IpV}_{{iv}_{b}}} ) ]\end{matrix}$$

Moreover, the following expression can be obtained for the initial condition with both observed-modes-variables:

$$\begin{matrix}P ( ( [ {⋂}_{{u}_{b}} ( {M}_{{M}_{{w}_{b}}}^{{C}_{{u}_{b}}} ) ] ⋂ [ {⋂}_{{ov}_{b}} ( {S}_{{S}_{{p}_{b}}}^{{OpV}_{{ov}_{b}}} ) ] ⋂ [ {⋂}_{{iv}_{b}} ( {S}_{{S}_{{p}_{b}}}^{{IpV}_{{iv}_{b}}} ) ] \vert [ {⋂}_{{u}_{b}^{′}} ( {M}_{{M}_{{w}_{b}^{′}}}^{{C}_{{u}_{b}^{′}}} ) ] \\ ⋂ [ {⋂}_{{ov}_{b}^{′}} ( {S}_{{S}_{{p}_{b}^{′}}}^{{OpV}_{{ov}_{b}^{′}}} ) ] ) ) = [ {\prod }_{{u}_{b}} P ( {M}_{{M}_{{w}_{b}}}^{{C}_{{u}_{b}}} ) ] [ {\prod }_{{iv}_{b}} P ( {S}_{{S}_{{p}_{b}}}^{{IpV}_{{iv}_{b}}} ) ]\end{matrix}$$

The probabilities defined in these equations are for an individual branch, P(Branch#). The terms on the right-hand side of these equations are the required input for the analysis. The values for these parameters can be obtained from the operational history, design specifications, expert's opinion, regulatory requirements, etc. A relative weight of a branch is obtained by normalizing the probability of an individual branch, using the following expression:

$$P ( Branch \# ) = \frac{P ( Branch \# )}{{\sum }_{Bn} P ( Branch Bn )} , Bn is the index of a branch$$

### System and Methods for Implementing BLIPS

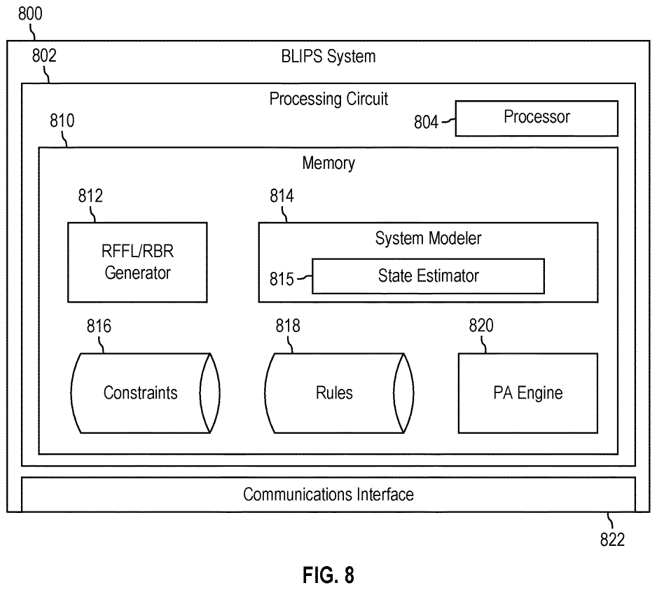

Referring now to FIG. 8, a diagram of a system 800 for implementing BLIPS is shown, according to some implementations. System 800 is shown to include a processing circuit 802 that includes a processor 804 and a memory 810. Processor 804 can be a general-purpose processor, an application specific integrated circuit (ASIC), one or more field programmable gate arrays (FPGAs), a group of processing components (e.g., a central processing unit (CPU)), or other suitable electronic processing structures. In some implementations, processor 804 is configured to execute program code stored on memory 810 to cause system 800 to perform one or more operations, as described below in greater detail. It will be appreciated that, in implementations where system 800 is part of another computing device, the components of system 800 may be shared with, or the same as, the host device. For example, if system 800 is implemented via a server (e.g., a cloud server), then system 800 may utilize the processing circuit, processor(s), and/or memory of the server to perform the functions described herein.

Memory 810 can include one or more devices (e.g., memory units, memory devices, storage devices, etc.) for storing data and/or computer code for completing and/or facilitating the various processes described in the present disclosure. In some implementations, memory 810 includes tangible (e.g., non-transitory), computer-readable media that stores code or instructions executable by processor 804. Tangible, computer-readable media refers to any physical media that is capable of providing data that causes system 800 to operate in a particular fashion. Example tangible, computer-readable media may include, but is not limited to, volatile media, non-volatile media, removable media and non-removable media implemented in any method or technology for storage of information such as computer readable instructions, data structures, program modules or other data. Accordingly, memory 810 can include random access memory (RAM), read-only memory (ROM), erasable programmable read-only memory (EPROM), electronically erasable programmable read-only memory (EEPROM), hard drive storage, temporary storage, non-volatile memory, flash memory, optical memory, or any other suitable memory for storing software objects and/or computer instructions. Memory 810 can include database components, object code components, script components, or any other type of information structure for supporting the various activities and information structures described in the present disclosure. Memory 810 can be communicably connected to processor 804, such as via processing circuit 802, and can include computer code for executing (e.g., by processor 804) one or more processes described herein.

While shown as individual components, it will be appreciated that processor 804 and/or memory 810 can be implemented using a variety of different types and quantities of processors and memory. For example, processor 804 may represent a single processing device or multiple processing devices. Similarly, memory 810 may represent a single memory device or multiple memory devices. Additionally, in some implementations, system 800 may be implemented within a single computing device (e.g., one server, one housing, etc.). In other implementations, system 800 may be distributed across multiple servers or computers (e.g., that can exist in distributed locations). For example, system 800 may include multiple distributed computing devices (e.g., multiple processors and/or memory devices) in communication with each other that collaborate to perform operations. For example, but not by way of limitation, an application may be partitioned in such a way as to permit concurrent and/or parallel processing of the instructions of the application. Alternatively, the data processed by the application may be partitioned in such a way as to permit concurrent and/or parallel processing of different portions of a data set by the two or more computers.

Memory 810 is shown to include an RFFL/RBR generator 812—herein referred to simply as “generator 812”—configured to generate RFFL and RBRs from FFL and RBs, respectively, for a modeled system. Put another way, generator 812 is configured to derive RBRs from BRs and to derive RFFL from FFL for the modeled system. As described herein, BRs and FFL may be stored in a rules database 818. For example, BRs and FFL may be predefined rules/functions for various components across systems (e.g., tanks, pipes, pumps, etc.). Likewise, the derived RBRs and RFFL can be stored in rules database 818 after being generated. RBRs and RFFLs can be derived using the various functions described above, e.g., using PL with SMT.

Memory 810 is also shown to include a system modeler 814 configured to model faults in a system. As shown, system modeler 814 can further include a state estimator 815 configured to estimate the state of various functions associated with a model of the system. To this point, system modeler 814 and state estimator 815 can collectively implement the methodology shown in FIG. 2 and described above. In particular, for functions with known states, system modeler 814 can first extract RFFLs (e.g., from generator 812) and then generate a set of relevant components associated with the RFFLs. Then, RBRs can be identified for the relevant components, which are in turn used to determine variable relations between relevant components. Likewise, system modeler 814 can generate a set of associated components connected to the relevant components in the modeled system. Then, RBRs can be identified for the associated components, which are in turn used to determine variable relations between associated components. State estimator 815 may then estimate the state of various other functions (e.g., functions without a known state) related to both the relevant and associated components. In some implementations, state estimator 815 references constraints 816 in estimating states, as discussed above. As also discussed above, system modeler 814 and/or state estimator 815 may implement PA to enhance the state estimations.

In some implementations, memory 810 can further include a probabilistic augmentation (PA) engine 820 for BLIPS-PA, as described above. The input to PA engine 820 is one or more sequences generated by system modeler 814 (e.g., BLIPS). In some implementations, PA engine 820 further receives user-identified parameters (e.g., controlled and observed) along with the intervals of probability for the observed parameters. The output of PA engine 820 may be a graphical representation of variation in the probability of occurrence of a controlled parameter against the predefined range(s) of the observed parameter(s). In some implementations, the output of PA engine 820 is provided via a user interface, e.g., by outputting to a display or another computing device via a communications interface 822, as described below.

Communications interface 822 generally facilitates communications between system 800 and any external components or devices. For example, communications interface 822 can provide means for transmitting data to, or receiving data from, a remote computing device (e.g., another computer, a server, etc.). Accordingly, communications interface 822 can be or can include a wired or wireless communications interface (e.g., jacks, antennas, transmitters, receivers, transceivers, wire terminals, etc.) for conducting data communications, or a combination of wired and wireless communication interfaces. In some implementations, communications via communications interface 822 are direct (e.g., local wired or wireless communications) or via a network (e.g., a WAN, the Internet, a cellular network, etc.). For example, communications interface 822 may include one or more Ethernet ports for communicably coupling system 800 to a network (e.g., the Internet). In another example, communications interface 822 can include a Wi-Fi transceiver for communicating via a wireless communications network. In yet another example, communications interface 822 may include cellular or mobile phone communications transceivers.

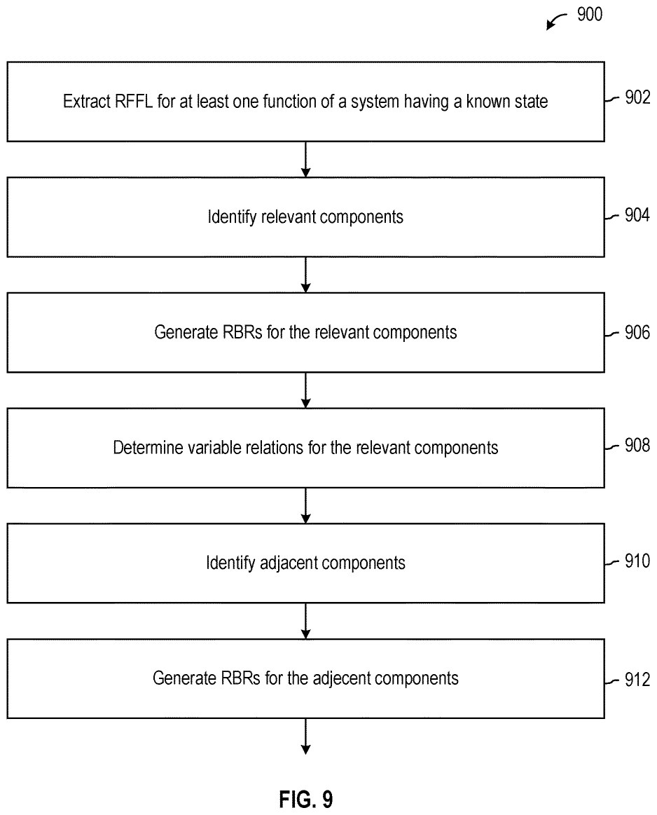

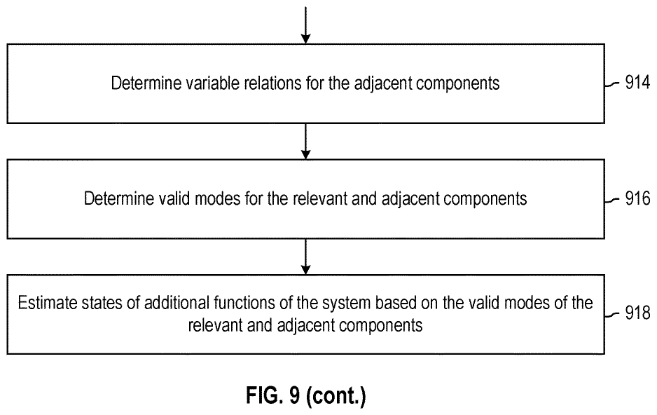

Referring now to FIG. 9, a flow chart of a process 900 for backwards failure propagation is shown, according to some implementations. In particular, process 900 generally follows the BLIPS methodology described above for back-propagating failures in a modeled system. In some implementations, process 900 is implemented by system 800, as described above. It will be appreciated that certain steps of process 900 may be optional and, in some implementations, process 900 may be implemented using less than all of the steps. It will also be appreciated that the order of steps shown in FIG. 9 is not intended to be limiting.

At step 902, RFFLs are extracted for at least one function of the system being modeled. As described above, RFFLs are derived from FFL (e.g., as in ISFA). Specifically, after re-writing FFLs using the contrapositive rule (a→b)↔(¬b→¬a), RFFLs can be derived using the rules of inference and the equivalence laws of the propositional logic. A function associates with two or more RFFLs, depending upon the number of states the function is mapped onto. Each RFFL represents modes of components implied by a state of the function described above (e.g., RFFLₖ_{^{r}}(Fₕ)). BRs and constraints are used as the premises for the derivation. The derivation for RBRs is carried out using the same procedure as RFFL, e.g., by contraposition and simplification. A component may have multiple RBRs, each of them presenting a combination of the physical variables of a component.

In some implementations, RFFLs are generated using SMT and/or PL's rules of inference (ROI). For a given component, SMT and ROI are also used to determine the valid modes and/or states of physical variables depending upon the extent of available knowledge. As mentioned above, the initial state of a system can be defined by any of the following entities or any combination of them: functional state(s), mode(s) of a component, or state(s) of physical variable(s). In some implementations, it is assumed that functional states are conditionally independent. In some implementations, independence between the modes of different components, the output physical variables of different components, and the input physical variables of different components is also assumed. It should also be noted that the common physical variable(s) at the interface of two components bear the same state (e.g., output flowrate (Qout1) from pipe-1 transfers to a serially attached Pipe-2, then the input flowrate (Qin2) will have the same state as Qout1).

At step 904, relevant components are identified. As mentioned above, relevant components are components that serve a function; in this case, the function(s) having a known state. In this regard, relevant components can be identified for each of the function(s) having a known state to create the set of relevant components. Further, for each component of the set of relevant components, component modes can be inferred using the RFFLs identified at step 902 to generate a set of inferred modes for the relevant components.

At step 906, RBRs are generated for the relevant components using the equation for RBRⱼ_{^{r}} presented above. As discussed above, RBRs are derived from BRs and the pertinent constraints for each of the relevant components. In some implementations, RBRs are generated using SMT and/or PL's ROI. For a given component, SMT and ROI are also used to determine the valid modes and/or states of physical variables depending upon the extent of available knowledge.

At step 908, variable relations are determined for the relevant components according to R^{V}(C_{qf}) as defined above. As mentioned, variable relations are qualitative equations depicting the relation between the physical variables of the components.

At step 910, adjacent components are identified. As mentioned above, adjacent components are components which are connected to the relevant component(s). For example, adjacent components may be immediately neighboring the relevant components in the system. In some implementations, the adjacent components are identified from a system diagram and/or the model of the system.

At step 912, RBRs are generated for the adjacent components using the equation for RBRⱼ_{^{r}} presented above. As discussed above, RBRs are derived from BRs and pertinent constraints for each of the adjacent components. In some implementations, prior to generating RBRs for the adjacent components, the adjacent component set and the relevant component set are disjointed by eliminating any components from the adjacent component set that are common/shared with the relevant component set.

At step 914, variable relations are determined for the adjacent components as defined by

$${R}^{V} ( {C}_{qc}^{adj} )$$

above. As mentioned above, the variable relations of the relevant components can be used to infer the variable relations of the adjacent components, in conjunction with the RBRs for the adjacent components.

At step 916, valid modes for the relevant and adjacent components are determined. In some implementations, this step includes identifying functions related to the relevant and adjacent components. Then, in some such implementations, the validity of any modes for the relevant and adjacent components can be checked. In particular, variable relations of the relevant and/or adjacent components may be assessed for contradiction with the system constraints, to identify the valid component modes. As mentioned above, system constraints are expressions including physical variables that describe the limitation engendered by the physics (e.g., the electrical current would be zero without a potential difference) or the constraints that are intended to be a part of the design.

At step 918, the state(s) of additional functions of the system are estimated based on the valid modes. In some implementations, the valid modes of the adjacent components are used with the FFL for the related functions to determine the states of the function(s) served by the adjacent component(s). Similarly, the valid modes of the relevant components are used with the FFL for the function related to the relevant components, e.g., for which a state is not initially known (e.g., at step 902). This loop/step can be repeated to update the relevant and adjacent component sets until all the components are covered.

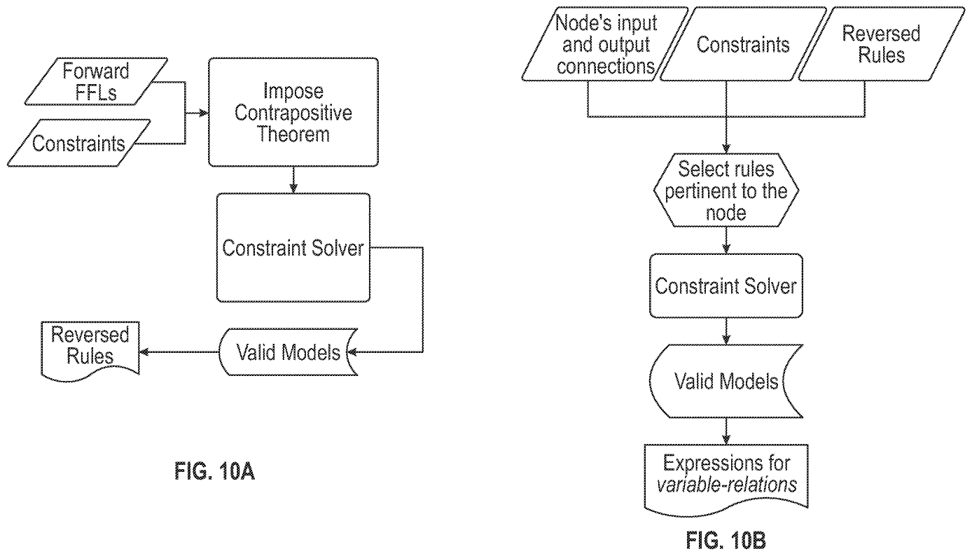

Referring now to FIG. 10, a flow chart of one example implementation of BLIPS is shown, according to some implementations. Specifically, on the left-hand side of FIG. 10, a sub-diagram is shown where traditional rules (e.g., BRs) and constraints are provided as input to the solver. The relevant constraints are selected, and all the possible models that satisfy the premises are obtained using the proof by contraposition. For the inference of variable relations at each node, shown on the right-hand side of FIG. 10, the reversed rules and constraints are solved together to obtain the valid models which are the variable relations, and the physical variables substitutions are made according to the map of the component's input/output connections. In some implementations, BLIPS is implemented using an SMT solver. Therefore, the zeroth-order logic can be efficiently handled. The solver can derive the RFFL and RBRs when provided with traditional FFL, traditional BRs, and system constraints, and it can infer the state of the system (e.g., component modes, physical variables, and functional states) at each node of the system model, constraints, and the reversed rules.

### Comparison to Existing Design Safety Analysis Techniques

Prevailing methods to perform design safety analysis include Failure Mode and Effect Analysis (FMEA), Fault Tree Analysis (FTA), and Probabilistic Risk Analysis (PRA). Fault analysis performed using PRA and FMEA is based on the sequence of events and cause-effect relationship provided by specialists. FMEA is an inductive reasoning process that assigns a risk priority number to each of the system's components. It is based on an expert's design evaluation using component failure modes and predicting the impact of those faults. FMEA limits the analysis to a single fault in isolation and does not examine component-level interaction. Moreover, it is highly dependent on the executor's level of knowledge.

PRA uses a combination of event trees and fault trees to quantify the probability of a failure for a collection of provided initiating events. To calculate the system failure probability, the analyst must choose accident progression scenarios for initiating events based on the experts' understanding of the system. The final results of PRA are frequencies (levels 1 and 2) and radiological consequences (level 3), which are not always dependent on the actual sequences. However, the failure or success probability (branch probabilities) of an event within a scenario is independent of the sequence of events.

FTA is utilized to calculate the failure probability of the event, using the minimal cutest obtained from the deductive analysis. FTA is a deductive reasoning technique that starts with a consequence, called top-event, and works its way down to a logical expression made up of basic events. It is worth noting that FTA is static in nature, does not recognize partial failure, and can only examine one top event at a time. Improved FTA techniques use specific gates, such as functional dependency gates, spares gates, and other types of gates, in conjunction with Markov chains to treat functional dependencies and scenarios with redundancies. However, a single deductive analysis method is desired that provides a unified picture of the functional analysis, incorporation of temporal behavior, and consideration of system physics. FTA is a Boolean-logic-based technique to obtain the minimal cut sets in terms of basic events. In contrast, BLIPS and/or BLIPS-PA rely on propositional logic to identify all the possible system configurations for the failure of interest, which supports inference.

Some algorithms have been introduced to automatically generate the fault trees, for instance, by using digraph models, Unified Modeling Language (UML) models, the Requirements State Machine Language (RSML) specifications, Fault Tolerant Data Flow (FTDF), Little-JIL process definition, and a combination of digraphs with deep learning. They define the relationships between the components based on the failure of signal flow. For some methods, the functional inter-dependencies need to be explicitly identified. However, while traversing backward, BLIPS considers both the possibility of the preceding component in the back-tracked sequence being faulty and nominal instead of catenating a chain of faulty component modes, and the functional interdependencies are revealed as the result of the analysis. Moreover, BLIPS leverages physics, which governs the behavior of system components and their relationship to the system functions, to propagate the consequence (failure of interest) by logically inferring the system's state. It inherently allows the translation of a functional state into the modes of component(s), physical variables, and the states of other functions, without explicitly identifying the functional interdependencies in the system. Furthermore, in addition to the binary states (e.g., operating and failed states), BLIPS also allows intermediate states, such as degraded state.

Among the backtracking methods, the reverse Monte-Carlo method was introduced to diagnose the causes of specific failure conditions. This strategy was suggested to reduce computational overload and increase precision. Another backtracking approach uses the Cell-to-Cell Mapping Technique (CCMT) and the Markovian framework to identify the probability of system states that may lead to the failure of interest. However, applying these methods to complex systems can be difficult. For instance, a system's detailed physics must be considered for the reverse Monte-Carlo method, which is difficult to obtain at an early design stage. Detailed physics and mathematical manipulations required for CCMT, such as matrix inversion, make these methods computationally expensive, and details about system physics are not available at an early design stage, especially for novel designs. Another backtracking algorithm using CCMT/Markov framework informally tracks the possible system configurations that may have existed in the past for a given system configuration. However, BLIPS obviates the need for operational data history. Moreover, the use of simplified discrete mathematics expressions does not impose a substantial burden on computing memory requirements, and the method can be applied in the early phases of design.

At the earlier stages of design, using a functional analysis approach allows a higher level of abstraction and allows the analyst to have a goal-oriented view of the system regarding safety and productivity. Quite a few approaches have been suggested that utilize the function-based approach. Function-Failure Design Method (FFDM), for example, is a design-aid tool that uses historical failure information to identify the potential failure modes of a proposed design. It is achieved by mapping the failure modes from the historical database derived from similar functions onto the system's function under consideration. Another tool, e.g., a Bayesian network-based functional analysis tool, implements functional failure propagation using a functional event network to identify functional dependencies. It also provides functional failure probabilities and insight into the importance of function(s) in terms of their position in the Bayesian network. However, these methods rely on feedback from similar designs to assess commonalities and help designers choose a relatively better design.

### Configuration of Certain Implementations

The construction and arrangement of the systems and methods as shown in the various implementations are illustrative only. Although only a few implementations have been described in detail in this disclosure, many modifications are possible (e.g., variations in sizes, dimensions, structures, shapes, and proportions of the various elements, values of parameters, mounting arrangements, use of materials, colors, orientations, etc.). For example, the position of elements may be reversed or otherwise varied, and the nature or number of discrete elements or positions may be altered or varied. Accordingly, all such modifications are intended to be included within the scope of the present disclosure. The order or sequence of any process or method steps may be varied or re-sequenced according to alternative implementations. Other substitutions, modifications, changes, and omissions may be made in the design, operating conditions, and arrangement of the implementations without departing from the scope of the present disclosure.

The present disclosure contemplates methods, systems, and program products on any machine-readable media for accomplishing various operations. The implementations of the present disclosure may be implemented using existing computer processors, or by a special purpose computer processor for an appropriate system, incorporated for this or another purpose, or by a hardwired system. Implementations within the scope of the present disclosure include program products including machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, CD-ROM or other optical disk storage, magnetic disk storage or other magnetic storage devices, or any other medium which can be used to carry or store desired program code in the form of machine-executable instructions or data structures, and which can be accessed by a general purpose or special purpose computer or other machine with a processor.

When information is transferred or provided over a network or another communications connection (either hardwired, wireless, or a combination of hardwired or wireless) to a machine, the machine properly views the connection as a machine-readable medium. Thus, any such connection is properly termed a machine-readable medium. Combinations of the above are also included within the scope of machine-readable media. Machine-executable instructions include, for example, instructions and data which cause a general-purpose computer, special purpose computer, or special purpose processing machines to perform a certain function or group of functions.

Although the figures show a specific order of method steps, the order of the steps may differ from what is depicted. Also, two or more steps may be performed concurrently or with partial concurrence. Such variation will depend on the software and hardware systems chosen and on designer choice. All such variations are within the scope of the disclosure. Likewise, software implementations could be accomplished with standard programming techniques with rule-based logic and other logic to accomplish the various connection steps, processing steps, comparison steps and decision steps.

It is to be understood that the methods and systems are not limited to specific synthetic methods, specific components, or to particular compositions. It is also to be understood that the terminology used herein is for the purpose of describing particular implementations only and is not intended to be limiting.

As used in the specification and the appended claims, the singular forms “a,” “an” and “the” include plural referents unless the context clearly dictates otherwise. Ranges may be expressed herein as from “about” one particular value, and/or to “about” another particular value. When such a range is expressed, another implementation includes from the one particular value and/or to the other particular value. Similarly, when values are expressed as approximations, by use of the antecedent “about,” it will be understood that the particular value forms another implementation. It will be further understood that the endpoints of each of the ranges are significant both in relation to the other endpoint, and independently of the other endpoint.

“Optional” or “optionally” means that the subsequently described event or circumstance may or may not occur, and that the description includes instances where said event or circumstance occurs and instances where it does not.

Throughout the description and claims of this specification, the word “comprise” and variations of the word, such as “comprising” and “comprises,” means “including but not limited to,” and is not intended to exclude, for example, other additives, components, integers or steps. “Exemplary” means “an example of” and is not intended to convey an indication of a preferred or ideal implementation. “Such as” is not used in a restrictive sense, but for explanatory purposes.

Disclosed are components that can be used to perform the disclosed methods and systems. These and other components are disclosed herein, and it is understood that when combinations, subsets, interactions, groups, etc. of these components are disclosed that while specific reference of each various individual and collective combinations and permutation of these may not be explicitly disclosed, each is specifically contemplated and described herein, for all methods and systems. This applies to all aspects of this application including, but not limited to, steps in disclosed methods. Thus, if there are a variety of additional steps that can be performed it is understood that each of these additional steps can be performed with any specific implementation or combination of implementations of the disclosed methods.

### ABBREVIATIONS AND SYMBOLS

TABLE VI
Index of Nomenclature

| Symbol | Meaning |
|---|---|
| ? | Mathematical operators: ‘=’, ‘<’, ‘>’, etc |
| ¿ | Logic symbol: ‘∧’, ‘∨’, ‘⊕’, etc. |
| ∈ | Member of |
| adj | Adjacent |
| b | Index of sub-RFFL in a fuzzy set |
| B | Total number of sub-RFFLs for the given RFFL |
| BLIPS | Backwards Logic Inference based Propagation for System analysis |
| BR | Behavioral Rule |
| RBR | Reversed Behavioral Rule |
| C | A component of a given system |
| C | Set containing all the components of the system |
| c | Index of components in S1/S2 |
| Constr | Constraints |
| C_{R}, [symbol] _{R} | Set containing all relevant components of given function |
| ${𝒞}_{B}^{′}$ | Set of components of the branch for whose associated physical |
| | variables are observed-variables |
| [symbol] _{B} | Set of components of the branch for whose associated physical |
| | variables are not observed-variables |
| DO | Dryout |
| F, [symbol] | Set containing all the functions of a system |
| F | A function of a given system |
| f | Index for functions′ respectively for S1 |
| F′, [symbol] ′ | Set of functions whose state is initially known |
| F″ | Functions (other than the initially known) for adjacent |
| | components in S3 |
| F²′ | Functions (other than the initially known) for relevant components |
| | in S1 |
| FFL | Functional Failure Logic |
| RFFL | Reversed Functional Failure Logic |
| h | Index for functions in ‘F’ |
| h′ | Index for functions in ‘F” |
| h″ | Index of functions in F” |
| h²′ | Index of functions in F²′ |
| i | Index of valid modes for a component |
| IpV | Input physical Variables |
| iv_{b} | Index for states of physical variables in [symbol] _{B} |
| ${iv}_{b}^{′}$ | $Index for states of physical variables in {𝒮}_{B}^{′}$ |
| j | Index for BRs for a component |
| j^{T} | Index for RBRs of a component |
| k | Index for FFL of a function |
| k^{r} | Index for RFFLs of a function |
| L | Lost state of a function |
| L( ) | Likelihood |
| L?Lₓₓₓ | Level of fluid |
| m | Membership function of a sub-RFFL for a fuzzy set |
| M, [symbol] | Set containing all the modes of a component |
| M | Mode of a component |
| ${M}_{ic}^{adj}$ | Set of valid modes of adjacent components |
| M_{ic} | Set of valid modes of relevant components |
| ${M}_{w , Valid}^{ic}$ | A valid component mode |
| ${M}_{Mode}^{Component}$ | Representation of Mode of a Component with its mode |
| ${ℳ}_{B}^{′}$ | $Set of modes for each component in {𝒞}_{B}^{′}$ |
| [symbol] _{B} | Set of modes for each component in [symbol] _{B} |
| NOM | Nominal |
| O | Operating state of a function |
| OF | Overflow |
| OpV | Output physical Variables |
| ov_{b} | $Index for physical variables in {𝒱}_{o}^{B}$ |
| ${ov}_{b}^{′}$ | $Index for physical variables in {𝒱}_{o}^{′ B}$ |
| p | Index for states of a function in set ‘S’ |
| P | Pressure |
| p_{b} | Index for states of variable in [symbol] _{B} |
| ${p}_{b}^{′}$ | $Index for states of variable in {𝒮}_{B}^{′}$ |
| pᵢₙ | Input Pressure |
| pₒᵤₜ | Output Pressure |
| ${𝒫}_{Value of probability}^{Variable}$ | Representation of Probability of a variable with its value |
| ${ℙ}_{Condition}^{Variable}$ | Representation of Conditional Probability of a variable with the condition |
| P( ) | Prior probability |
| P(;) | Probability of a member belonging to a fuzzy set given the |
| | membership function |
| PA | Probabilistic Augmentation |
| Q | Flow rate |
| q | Index of relevant/adjacent components |
| Q_{iP} | Input flowrate of pipe |
| Q_{iT} | Input flowrate of tank |
| Q_{oP} | Output flowrate of pipe |
| Q_{oT} | Output flowrate of Tank |
| R^{V} | Variable relations for relevant components |
| R^{V,adj} | Variable relations for adjacent components |
| R^{V,Constr} | Variable relations of constraints |
| S, [symbol] | Set containing all the states of a function |
| s | Total number of Behavior Rules for a component |
| S | State of a function or of a physical variable |
| ${S}_{State}^{Physical Variable}$ | Representation of State of a physical variable |
| S1 | Set of relevant components for functions in ‘F” |
| S2 | Set of adjacent components |
| S3 | S2 - (S1 ∩ S2) |
| ${𝒮}_{B}^{′}$ | $Set of states for the each physical variable in {𝒱}_{o}^{′ B}$ |
| [symbol] _{B} | $Set of states for the each physical variable in {𝒱}_{o}^{B}$ |
| T | Temperature |
| t | Total number of FFL for a function |
| u | Index for components in ‘C’ |
| u_{b} | Index for components in [symbol] _{B} |
| u′ | Index for components in ‘C_{R’} |
| ${u}_{b}^{′}$ | $Index for the components in {𝒞}_{B}^{′}$ |
| v | Index for types of physical variables |
| Vᵢₙ | Input Voltage |
| Vₒᵤₜ | Output Voltage |
| ${𝒱}_{i}^{B}$ | Set of input physical variables (IpV) for the terminal components |
| | of [symbol] _{B} |
| ${𝒱}_{o}^{′ B}$ | $Set of output physical variables ( Op V ) for the components in {𝒞}_{B}^{′}$ |
| ${𝒱}_{o}^{B}$ | Set of output physical variables (OpV) for the components in [symbol] _{B} |
| w | Index for modes of a component in ‘M’ or [symbol] |
| w_{b} | Index for modes of a component in [symbol] _{B} |
| ${w}_{b}^{′}$ | $Index for modes of a component in {ℳ}_{B}^{′}$ |
| L_{LTH} | Lower-level threshold |
| L_{UTH} | Upper-level threshold |
| X_{Nom} | Nominal value of any variable X |
| X_{L} | Any function X is Lost |
| X_{O} | Any function X is Operating |

What is claimed is:

1. A method for backward propagation of failures in a system, the method comprising:
extracting, from a model of the system, reverse functional failure logic (RFFL) for at least one function of the system having a known state, wherein the RFFL is an inverse of predefined function failure logic (FFL) for the at least one function;
identifying a set of relevant components of the system associated with the at least one function;
generating first reverse behavior rules (RBRs) for each of the set of relevant components from predefined first behavior rules (BRs);
determining first variable relations for each of the set of relevant components, wherein the first variable relations are qualitative equations depicting a relation between physical variables of respective components of the set of relevant components;
identifying a set of adjacent components of the system, each of the set of adjacent components connected to at least one of the set of relevant components in the model of the system;
identifying second RBRs for each of the set of adjacent components from predefined second BRs;
determining second variable relations for each of the set of adjacent components based on the second RBRs, wherein the second variable relations are qualitative equations depicting a physical connection between each of the set of adjacent components and a corresponding one of the set of relevant components;
determining valid modes for each of the set of relevant components and each of the set of adjacent components based on constraints of the system; and
estimating, based on the valid modes, (i) a state for one or more additional functions of the system related to the set of relevant components, and (ii) a state for one or more functions of the system related to the set of adjacent components.

2. The method of claim 1, further comprising determining valid modes for each of the set of relevant components prior to generating the first RBRs.

3. The method of claim 1, further comprising identifying the one or more additional functions of the system related to the set of relevant components based on the valid modes for the set of relevant components.

4. The method of claim 1, wherein the state for the one or more additional functions of the system related to the set of relevant components is estimated based on FFL of the set of relevant component in addition to the valid modes.

5. The method of claim 1, wherein the state for the one or more functions of the system related to the set of adjacent components is estimated based on FFL of the set of adjacent component in addition to the valid modes.

6. The method of claim 1, further comprising removing, from the set of adjacent components, any adjacent component that is also found in the set of relevant components.

7. The method of claim 1, further comprising evaluating at least one of the first variable relations or the second variable relations against constraints defined in the model of the system.

8. The method of claim 7, wherein the valid modes for each of the set of relevant components and each of the set of adjacent components based on constraints of the system are further determined based on the evaluation with respect to the constraints.

9. The method of claim 7, wherein the constraints are expressions relating to physical variables that describe limitations of the system.

10. A system comprising:
At least one processor; and
memory having instructions stored thereon that, when executed by the processor, cause the system to:
extract, from a model of an external system, reverse functional failure logic (RFFL) for at least one function of the external system having a known state, wherein the RFFL is an inverse of predefined function failure logic (FFL) for the at least one function;
identify a set of relevant components of the external system associated with the at least one function;
generate first reverse behavior rules (RBRs) for each of the set of relevant components from predefined first behavior rules (BRs);
determine first variable relations for each of the set of relevant components, wherein the first variable relations are qualitative equations depicting relationships between physical variables of respective components of the set of relevant components;
identify a set of adjacent components of the external system, each of the set of adjacent components connected to at least one of the set of relevant components in the model of the external system;
identify second RBRs for each of the set of adjacent components from predefined second BRs;
determine second variable relations for each of the set of adjacent components based on the second RBRs, wherein the second variable relations are qualitative equations depicting a physical connection between each of the set of adjacent components and a corresponding one of the set of relevant components;
determine valid modes for each of the set of relevant components and each of the set of adjacent components based on the first variable relations and the second variable relations, respectively; and
estimate, based on the valid modes, (i) a state for one or more additional functions of the external system related to the set of relevant components, and (ii) a state for one or more functions of the external system related to the set of adjacent components.

11. The system of claim 10, wherein the instructions further cause the system to:
determine valid modes for each of the set of relevant components prior to generating the first RBRs.

12. The system of claim 10, wherein the instructions further cause the system to:
identify the one or more additional functions of the external system related to the set of relevant components based on the valid modes for the set of relevant components.

13. The system of claim 10, wherein the state for the one or more additional functions of the external system related to the set of relevant components is estimated based on FFL of the set of relevant component in addition to the valid modes.

14. The system of claim 10, wherein the state for the one or more functions of the external system related to the set of adjacent components is estimated based on FFL of the set of adjacent component in addition to the valid modes.

15. The system of claim 10, wherein the instructions further cause the system to:
remove, from the set of adjacent components, any adjacent component that is also found in the set of relevant components.

16. The system of claim 10, wherein the instructions further cause the system to:
evaluate at least one of the first variable relations or the second variable relations against constraints defined in the model of the external system to determine the valid modes.

17. The system of claim 16, wherein the valid modes for each of the set of relevant components and each of the set of adjacent components are further determined based on the evaluation with respect to the constraints.

18. The system of claim 16, wherein the constraints are expressions relating to physical variables that describe limitations of the external system.

19. A non-transitory computer readable medium having instructions stored thereon that, when executed by the processor, cause a device to:
extract, from a model of a system, reverse functional failure logic (RFFL) for at least one function of the system having a known state, wherein the RFFL is an inverse of predefined function failure logic (FFL) for the at least one function;
identify a set of relevant components of the system associated with the at least one function;
generate first reverse behavior rules (RBRs) for each of the set of relevant components from predefined first behavior rules (BRs);
determine first variable relations for each of the set of relevant components, wherein the first variable relations are qualitative equations depicting a relation between physical variables of respective components of the set of relevant components;
identify a set of adjacent components of the system, each of the set of adjacent components connected to at least one of the set of relevant components in the model of the system;
identify second RBRs for each of the set of adjacent components from predefined second BRs;
determine second variable relations for each of the set of adjacent components based on the second RBRs, wherein the second variable relations are qualitative equations depicting a physical connection between each of the set of adjacent components and a corresponding one of the set of relevant components;
determine valid modes for each of the set of relevant components and each of the set of adjacent components based on constraints of the system; and
estimate, based on the valid modes, (i) a state for one or more additional functions of the system related to the set of relevant components, and (ii) a state for one or more functions of the external related to the set of adjacent components.

20. The computer readable medium of claim 19, wherein the instructions further cause the device to:
remove, from the set of adjacent components, any adjacent component that is also found in the set of relevant components.
